(19) United States
(12) Patent Application Publication
(10) Pub. No.: US 2026/0337013 A1
(43) Pub. Date: Oct. 29, 2026

(54) DIELECTROPHORETIC-ACOUSTOPHORETIC DUAL-SENSING AC ELECTROLUMINESCENT DEVICE

(71) Applicant: UIF (University Industry Foundation), Yonsei University, Seoul (KR)

(72) Inventors: Cheol Min PARK, Seoul (KR); Hyung Suk LEE, Seoul (KR); Jong Woong PARK, Seoul (KR); Don Young KANG, Seoul (KR); Ji Hye JANG, Danyang-gun (KR); Byung Jun KANG, Seoul (KR)

(73) Assignee: UIF (University Industry Foundation), Yonsei University, Seoul (KR)

(21) Appl. No.: 19/659,322

(22) Filed: Apr. 27, 2026

(30) Foreign Application Priority Data
Apr. 29, 2025 (KR) 10-2025-0056586
Apr. 21, 2026 (KR) 10-2026-0071689

(51) Int. Cl. B81B 7/02; H10H 20/813

(52) U.S. Cl. CPC B81B 7/02; H10H 20/813; B81B 2201/0257; B81B 2201/0292; B81B 2203/04; B81B 2207/99

(57) ABSTRACT

A dual-sensing alternating current electroluminescent device is disclosed. The device comprises: an acoustic wave generating unit comprising a substrate, a first electrode formed adjacent to the substrate, and a second electrode formed adjacent to the substrate and spaced apart from the first electrode; a matrix unit positioned on the acoustic wave generating unit and comprising a chamber capable of receiving a fluid therein, a fluid received within the chamber, and conductive particles dispersed in the fluid; an electroluminescent layer positioned on the matrix unit and configured to emit light when a voltage is applied thereto; a third electrode positioned on the electroluminescent layer and formed coplanar with the electroluminescent layer; and a fourth electrode positioned on the electroluminescent layer, formed coplanar with the electroluminescent layer, and spaced apart from the third electrode.

### CROSS-REFERENCE TO RELATED APPLICATION

This application claims priority from Korean Patent Application Nos. 10-2025-0056586, filed on Apr. 29, 2025, and 10-2026-0071689, filed on Apr. 21, 2026, in the Korea Intellectual Property Office, and all the benefits accruing therefrom under 35 U.S.C. 119. The contents of each of the above applications are incorporated herein in their entirety by reference.

### BACKGROUND

### Field

The present invention relates to a dielectrophoretic-acoustophoretic dual-sensing alternating current electroluminescent device based on an alternating current (AC)-driven electroluminescent (EL) display, and more particularly, to a dual-sensing electroluminescent display capable of simultaneously sensing and visualizing in real time both dielectrophoretic (DEP) and acoustophoretic (ACP) forces, wherein the luminescent state dynamically changes and can be repeatedly rewritten in response to such physical stimuli. The present invention provides, in particular, a structure capable of intuitively displaying the intensity or presence of DEP and ACP forces in the form of electroluminescence in response to physical stimuli, namely electric fields and acoustic waves, that cannot be directly perceived by humans, thereby holding potential for extension into next-generation display technology that enables simultaneous visualization and sensing of multiple physical stimuli.

### Description of Related Art

As technologies utilizing dielectrophoretic and acoustophoretic forces continue to advance, there is a growing need for devices capable of intuitively and dynamically visualizing such forces. Conventional analysis of physical forces relies on complex equipment or indirect measurement methods, which limits the ability of users to immediately observe and interpret responses. Accordingly, there is a demand for technical alternatives capable of providing rapid, real-time visual feedback.

More specifically, stimuli-responsive displays that react to various physical stimuli such as pressure, temperature, and humidity have attracted considerable attention in next-generation application fields such as electronic skin and the Internet of Things. However, in these conventional systems, the sensor that detects the stimulus and the display that visualizes it must be connected through a microprocessor, resulting in increased structural complexity and reduced energy efficiency. Such structural constraints also pose obstacles to the miniaturization and flexibility of the system.

As a technical approach to address these limitations, AC-driven electroluminescent displays capable of directly visualizing stimuli without a microprocessor have been proposed. While this approach offers the advantages of simplified structure and improved response speed, most stimuli-responsive displays have been limited to stimuli that can be directly perceived by humans. By contrast, the visualization of physical stimuli imperceptible to humans-such as electric fields, magnetic fields, ultrasound, and infrared radiation-remains insufficiently addressed.

Dielectrophoresis (DEP), which is induced by alternating current electric fields, is a highly useful physical mechanism enabling contactless manipulation, assembly, and separation of particles. DEP-based technologies offer high throughput and scalability, and have been employed across a wide range of fields including sensors, nanostructure manipulation, field-effect transistors, light sources, and light-emitting diodes. However, quantitative analysis of DEP-driven particle assembly processes requires complex electrical signal readout or microscopy-based image analysis, which poses an obstacle to achieving real-time human-readable output. The present inventors therefore recognized the need for a display capable of visualizing DEP in real time, overcoming such limitations.

Furthermore, particle structures formed by DEP are generally maintained in a stable state due to interactions such as van der Waals and dipolar attractions, making it technically challenging to disassemble and reassemble such structures. Accordingly, for a DEP-based display to be rewritable, a novel material-based strategy capable of efficiently disassembling the particle structures is required. From this perspective, the present inventors focused on the acoustophoretic force (ACP) based on acoustic waves, which is capable of precisely displacing and dispersing particles over a large area. In particular, ACP utilizing SAW devices or ultrasonic transducers traps particles at pressure nodes or antinodes, and has been applied across diverse fields including acoustic tweezers, patterning, holography, and non-destructive testing. The present inventors therefore recognized that integrating ACP into a DEP-based display would enable effective disassembly of conductive structures formed by DEP, and thereafter allow the realization of a dual-sensing rewritable display capable of reassembly.

### SUMMARY

The problem to be solved by the present invention is to provide a display device capable of intuitively visualizing and responsively interpreting dielectrophoretic (DEP) and acoustophoretic (ACP) forces without complex signal processing or optical systems. More specifically, the present invention aims to implement a device that provides a means of visually confirming the spontaneous assembly and disassembly of particles, thereby enabling real-time monitoring and intuitive control of the operational state of microparticle manipulation systems. In addition, based on dual-sensing characteristics that simultaneously respond to two distinct stimuli, namely electric fields and acoustic fields, the device is capable of qualitatively or quantitatively tracking changes in the intensity or spatial position of external stimuli, and such functionality may find applicability across a wide range of fields including sensors, displays, and bioanalytical systems. The present invention is directed to overcoming the limitations of conventional stimuli-responsive displays, including microprocessor dependency, complex structure, and limited range of perceivable stimuli, and to providing a rewritable display capable of visualizing in real time non-visible physical stimuli such as DEP and ACP without external sensors or processors, and of repeated use.

In one aspect, the present invention provides a dual-sensing alternating current electroluminescent device comprising: an acoustic wave generating unit comprising a substrate, a first electrode formed adjacent to the substrate, and a second electrode formed adjacent to the substrate and spaced apart from the first electrode; a matrix unit positioned on the acoustic wave generating unit and comprising a chamber capable of receiving a fluid therein, a fluid received within the chamber, and conductive particles dispersed in the fluid; an electroluminescent layer positioned on the matrix unit and configured to emit light when a voltage is applied thereto; a third electrode positioned on the electroluminescent layer and formed coplanar with the electroluminescent layer; and a fourth electrode positioned on the electroluminescent layer, formed coplanar with the electroluminescent layer, and spaced apart from the third electrode.

In one embodiment, the dual-sensing alternating current electroluminescent device may further comprise an acoustic wave power supply configured to apply a voltage to the first electrode and the second electrode to form a standing acoustic wave in the matrix unit.

In one embodiment, the substrate may be a piezoelectric substrate.

In one embodiment, the first electrode and the second electrode may be formed facing each other with the substrate interposed therebetween.

In one embodiment, the acoustic wave formed by the acoustic wave power supply may be a bulk acoustic wave.

In one embodiment, the first electrode and the second electrode may be formed coplanar and spaced apart from each other on the substrate.

In one embodiment, the acoustic wave formed by the acoustic wave power supply may be a surface acoustic wave.

In one embodiment, the acoustic wave power supply may provide a frequency range including a resonant frequency and/or an antiresonant frequency within a frequency range of about 13 to 15 MHz.

In one embodiment, the dual-sensing alternating current electroluminescent device may further comprise an alternating current power supply configured to apply an alternating current voltage to the third electrode and the fourth electrode.

In one embodiment, the first electrode and the second electrode may be formed in an interdigitated configuration.

In one embodiment, the acoustic wave power supply may supply power to a SAW device comprising two interdigital transducers (IDTs).

In one embodiment, the IDTs may be formed of aluminum on a LiNbO₃ substrate.

In one embodiment, the conductive particles may comprise carbon black microspheres.

In one embodiment, the conductive particles may comprise carbon black microspheres having a diameter of about 2 to 12 micrometers (μm).

In one embodiment, the fluid may be a non-polar fluid.

In one embodiment, the non-polar fluid may comprise n-hexadecane.

In one embodiment, the electroluminescent layer may comprise ZnS:Cu.

In one embodiment, the ZnS:Cu may have an average particle diameter of about 20 to 30 μm.

In one embodiment, the electroluminescent layer may be a composite film comprising ZnS:Cu phosphors and a polymer matrix.

In one embodiment, the polymer matrix may comprise P(VDF-TrFE-CFE).

In one embodiment, the thickness of the electroluminescent layer may be about 20 μm.

In one embodiment, the weight ratio of ZnS to polymer matrix in the electroluminescent layer may be about 4:1 to 13:1.

In one embodiment, when an alternating current voltage is applied to the third electrode and the fourth electrode and no standing acoustic wave is applied to the matrix unit through the first electrode and the second electrode, the conductive particles in the fluid may migrate by dielectrophoresis to form a conductive bridge connecting the third electrode and the fourth electrode in an upper portion of the fluid, thereby inducing light emission from the electroluminescent layer.

In one embodiment, when an acoustic wave is applied through the first electrode and the second electrode while the conductive bridge is formed, the conductive particles may migrate toward nodes of the standing acoustic wave and the conductive bridge may be disrupted, resulting in extinction of light emission from the electroluminescent layer.

In another aspect, the present invention provides a temperature sensing device comprising a dual-sensing alternating current electroluminescent device, the dual-sensing alternating current electroluminescent device comprising: an acoustic wave generating unit comprising a substrate, a first electrode formed adjacent to the substrate, and a second electrode formed adjacent to the substrate and spaced apart from the first electrode; a matrix unit positioned on the acoustic wave generating unit and comprising a chamber capable of receiving a fluid therein, a fluid received within the chamber, and conductive particles dispersed in the fluid; an electroluminescent layer positioned on the matrix unit and configured to emit light when a voltage is applied thereto; a third electrode positioned on the electroluminescent layer and formed coplanar with the electroluminescent layer; a fourth electrode positioned on the electroluminescent layer, formed coplanar with the electroluminescent layer, and spaced apart from the third electrode; an acoustic wave power supply configured to apply a voltage to the first electrode and the second electrode to form a standing acoustic wave in the matrix unit; and an alternating current power supply configured to apply an alternating current voltage to the third electrode and the fourth electrode.

In one embodiment, the substrate may be a piezoelectric substrate.

In one embodiment, the first electrode and the second electrode may be formed facing each other with the substrate interposed therebetween.

In one embodiment, the acoustic wave formed by the acoustic wave power supply may be a bulk acoustic wave.

In one embodiment, the first electrode and the second electrode may be formed coplanar and spaced apart from each other on the substrate.

In one embodiment, the acoustic wave formed by the acoustic wave power supply may be a surface acoustic wave.

In one embodiment, when an alternating current voltage is applied to the third electrode and the fourth electrode and no standing acoustic wave is applied to the matrix unit through the first electrode and the second electrode, the conductive particles in the fluid may migrate by dielectrophoresis to form a conductive bridge connecting the third electrode and the fourth electrode in an upper portion of the fluid, thereby inducing light emission from the electroluminescent layer.

In one embodiment, when a standing acoustic wave is applied through the first electrode and the second electrode while the conductive bridge is formed, the conductive particles may migrate toward nodes of the acoustic wave and the conductive bridge may be disrupted, resulting in extinction of light emission from the electroluminescent layer.

In one embodiment, the dual-sensing alternating current electroluminescent device may further comprise a controller configured to adjust a frequency of the acoustic wave power supply.

In one embodiment, the temperature sensing device may sense temperature by utilizing a shift in the frequency at which the acoustic wave power supply is capable of forming a standing acoustic wave to disrupt the conductive bridge, the shift occurring when acoustic transmission properties of the fluid change due to a variation in temperature.

In yet another aspect, the present invention provides a temperature sensing method comprising sensing temperature using the temperature sensing device according to the embodiment of the present invention.

In yet another aspect, the present invention provides a foreign substance sensing device comprising a dual-sensing alternating current electroluminescent device, the dual-sensing alternating current electroluminescent device comprising: an acoustic wave generating unit comprising a substrate, a first electrode formed adjacent to the substrate, and a second electrode formed adjacent to the substrate and spaced apart from the first electrode; a matrix unit positioned on the acoustic wave generating unit and comprising a chamber capable of receiving a fluid therein, a fluid received within the chamber, and conductive particles dispersed in the fluid; an electroluminescent layer positioned on the matrix unit and configured to emit light when a voltage is applied thereto; a third electrode positioned on the electroluminescent layer and formed coplanar with the electroluminescent layer; a fourth electrode positioned on the electroluminescent layer, formed coplanar with the electroluminescent layer, and spaced apart from the third electrode; an acoustic wave power supply configured to apply a voltage to the first electrode and the second electrode to form a standing acoustic wave in the matrix unit; and an alternating current power supply configured to apply an alternating current voltage to the third electrode and the fourth electrode.

In one embodiment, the substrate may be a piezoelectric substrate.

In one embodiment, the first electrode and the second electrode may be formed facing each other with the substrate interposed therebetween.

In one embodiment, the acoustic wave formed by the acoustic wave power supply may be a bulk acoustic wave.

In one embodiment, the first electrode and the second electrode may be formed coplanar and spaced apart from each other on the substrate.

In one embodiment, the acoustic wave formed by the acoustic wave power supply may be a surface acoustic wave.

In one embodiment, a fluid channel through which a second fluid passes may be further formed between the substrate and the matrix unit.

In one embodiment, when an alternating current voltage is applied to the third electrode and the fourth electrode and no acoustic wave is applied to the matrix unit through the first electrode and the second electrode, the conductive particles in the fluid may migrate by dielectrophoresis to form a conductive bridge connecting the third electrode and the fourth electrode in an upper portion of the fluid, thereby inducing light emission from the electroluminescent layer.

In one embodiment, when an acoustic wave is applied through the first electrode and the second electrode while the conductive bridge is formed, the conductive particles may migrate toward nodes of the standing acoustic wave and the conductive bridge may be disrupted, resulting in extinction of light emission from the electroluminescent layer.

In one embodiment, the dual-sensing alternating current electroluminescent device may be capable of sensing a foreign substance within the fluid channel.

In one embodiment, the foreign substance sensing device may sense a change in light emission intensity of the electroluminescent layer that occurs as a result of disruption and formation of the conductive bridge, the disruption and formation being caused by a change in whether the standing acoustic wave is formed, which in turn occurs when acoustic transmission properties of a material passing through the fluid channel change.

In one embodiment, the foreign substance may be a substance other than the second fluid or an air bubble.

In yet another aspect, the present invention provides a foreign substance sensing method comprising sensing a foreign substance using the foreign substance sensing device according to the embodiment of the present invention.

In yet another aspect, the present invention provides a motion tracking display in which a plurality of the foreign substance sensing devices according to the embodiment of the present invention are arranged, the fluid channels of the plurality of arranged foreign substance sensing devices are fluidically connected to each other at least in part, and movement of a foreign substance flowing within the fluidically connected fluid channels is visually confirmable by light emission from the foreign substance sensing devices.

In one embodiment, the plurality of arranged foreign substance sensing devices may be arranged in an array.

According to one embodiment of the present invention, an electroluminescent display is provided that enables real-time visualization of dielectrophoretic and acoustophoretic forces. The display comprises an electroluminescent layer driven by alternating current (AC) and a matrix layer comprising conductive microparticles designed to respond to external electrical or acoustic stimuli. When an AC electric field is applied between coplanar electrodes disposed on a substrate, conductive microparticles dispersed in a fluid medium are aligned by dielectrophoretic force, thereby forming a conductive bridge connecting the two electrodes. This conductive bridge establishes electrical continuity between the electrodes and applies a localized electric field to the electroluminescent layer, inducing light emission. The resulting electroluminescence can be modulated according to the presence, intensity, and frequency of the DEP field, thereby enabling visualization of the dielectrophoretic phenomenon. Conversely, when an acoustic wave is transmitted to the device, the previously formed conductive bridge is disrupted by the acoustophoretic force. The particles migrate toward the nodes or antinodes of the acoustic field, consequently disassembling the conductive pathway and extinguishing light emission. Such reversible switching behavior forms the basis of a reconfigurable display system capable of responding to both DEP and ACP stimuli. Since the electroluminescent characteristics of the display can be modulated according to the frequency and intensity of the DEP and ACP input signals, qualitative or quantitative analysis or visual mapping of both forces becomes possible. Accordingly, the device may be utilized as a visual resonator that responds sensitively to acoustic resonance modes or temperature changes.

According to one embodiment of the present invention, a dielectro-acoustophoretic dual-sensing electroluminescent display (DUET display) is provided. The display may comprise the following components: (i) a pair of coplanar electrodes disposed on the same plane; (ii) an emissive layer comprising inorganic electroluminescent phosphors; (iii) a chamber filled with carbon microspheres dispersed in a non-polar fluid; and (iv) a SAW device comprising two interdigital transducers (IDTs) formed on a piezoelectric substrate. When an AC voltage is applied between the coplanar electrodes, dielectrophoretic force is generated within the chamber, causing the carbon microspheres to self-assemble into dendritic conductive bridges. These bridges establish electrical connectivity between the electrodes and deliver a localized electric field to the emissive layer, thereby inducing light emission (On-mode). Conversely, when a surface acoustic wave is applied through the SAW device, the resulting acoustophoretic force disassembles the conductive bridges, interrupting the current pathway and extinguishing light emission (Off-mode). In the On-mode, light emission intensity is enhanced by DEP, while in the Off-mode, light emission is suppressed by ACP, thereby providing the possibility of quantitatively interpreting the intensities of DEP and ACP through changes in light emission intensity. Furthermore, since the nodal positions of the standing wave formed by periodically assembled microspheres shift with temperature, temperature changes can also be visually confirmed using this structure. According to another embodiment, the DUET display may be configured in an array format and applied to microfluidic channels, enabling real-time, contactless visualization of the movement paths of flowing air bubbles or particles. The light emission state of each display unit varies depending on the position at which the conductive bridge is formed or disrupted, thereby enabling high-resolution detection of the movement of components within the fluid.

The key effect of the present invention lies in the ability to visualize in real time, within a single device, the opposing effects exerted by electric fields (DEP) and acoustic fields (ACP) on particles. This enables intuitive observation of the assembly and disassembly processes of particles, and can be utilized for qualitative or quantitative interpretation of responses to externally applied physical stimuli. In particular, since the position and state of microparticles can be actively controlled using dielectrophoretic force and acoustic radiation force, functional scalability and design flexibility can be secured across a wide range of application fields including sensors, displays, and bioanalytical platforms.

More specifically, by exploiting the opposing actions of DEP and ACP on particle migration and bridge formation, a selective and rewritable sensing display can be realized. For example, when the resonant frequency of an acoustic wave device shifts due to a temperature change, this can be visually perceived through a change in the light emission pattern. In addition, changes in the position of flowing air bubbles or particles within a microfluidic system can be detected in real time in a contactless manner, enabling effective application to diagnostic or analytical platforms.

Accordingly, the dual-sensing electroluminescent display according to the present invention provides a rewritable platform capable of simultaneously sensing and visualizing DEP and ACP within a single planar device. Since non-visible stimuli that are difficult for humans to perceive can be visually represented without external circuits or complex sensors, the device is applicable across a wide range of fields including force sensing, visualization, microfluidic analysis, acoustic holography, and interactive displays.

### BRIEF DESCRIPTION OF DRAWINGS

FIG. 1A is an exploded schematic view of a DUET display together with a SAW device.

FIG. 1B is a scanning electron microscopy (SEM) image of the top cover of the DUET display.

FIG. 1C is a photograph of a DUET display mounted on a SAW device (top) and a zoomed-in photograph of an interdigital transducer (IDT) pattern on a lithium niobate (LiNbO₃) substrate (bottom).

FIG. 1D is a schematic diagram of the electrical impedance-luminance relationship of the DUET display in response to dielectrophoretic (DEP) and acoustophoretic (ACP) forces, with inset images of the DUET display in On-mode (left) and Off-mode (right) as viewed from above (z direction).

FIG. 1E is a schematic diagram of the operation mechanisms of the DUET display, showing the initial state (left), On-mode (center), and Off-mode (right).

FIG. 2A is a schematic diagram of particle movements under different DEP force intensities.

FIG. 2B is a graph showing a simulation of the real part of the Clausius-Mossotti factor (Re[f*CM(ω)]) for carbon microspheres in n-hexadecane.

FIG. 2C is a set of optical microscopy images of dendrite formations under different DEP forces.

FIG. 2D is a graph showing the total dendrite length as a function of DEP force.

FIG. 2E is a set of electroluminescence (EL) photographs of the DUET display showing its response to DEP forces.

FIG. 2F is a graph showing the electrical impedance change of the DUET display in response to DEP forces.

FIG. 2G is a graph showing the EL change of the DUET display in response to DEP forces.

FIG. 2H is a graph showing EL spectra of the DUET display under various operating voltages.

FIG. 2I is a graph showing luminance-voltage (L-V) characteristics of the DUET display, where solid lines are fits to an exponential function.

FIG. 2J is a graph showing EL area as a function of operating voltage.

FIG. 2K is a graph showing response time of the DUET display under various DEP frequencies.

FIG. 3A is a schematic diagram of the two operating modes of the DUET display.

FIG. 3B is a set of optical microscopy images of particle self-assembly formed by ACP forces.

FIG. 3C is a set of optical microscopy images of dendrite destruction under different ACP forces while a constant DEP force is applied.

FIG. 3D is a graph showing the total dendrite length as a function of ACP force while a constant DEP force is applied.

FIG. 3E is a set of EL photographs of the DUET display showing its response to ACP forces.

FIG. 3F is a graph showing the electrical impedance change of the DUET display in response to ACP forces.

FIG. 3G is a graph showing the EL change of the DUET display in response to ACP forces.

FIG. 3H is a graph showing EL spectra of the DUET display under various input voltages of the SAW device.

FIG. 3I is a graph showing EL intensity of the DUET display (left) and the response time (top) and recovery time (bottom) of the On-mode and Off-mode under various input voltages of the SAW device (right).

FIG. 3J is a graph showing the results of a dual-mode stability test over ten On-Off cycles, with corresponding EL photographs of the DUET display.

FIG. 4A is a schematic diagram of the temperature sensing mechanism of the DUET display.

FIG. 4B is a graph showing the S-parameter ((Sul) of the SAW device (black line) and the EL change of the DUET display (blue bars) under different input frequencies of the SAW device.

FIG. 4C is a graph showing |S₁₁| of the SAW device at different temperatures.

FIG. 4D is a graph showing the antiresonant frequency of the SAW device as a function of temperature.

FIG. 4E is a graph showing the EL change of the DUET display as a function of SAW input frequency at different temperatures.

FIG. 4F is a set of EL photographs of the DUET display corresponding to the EL changes shown in FIG. 4E.

FIG. 5A is a schematic diagram of the mechanism for detecting air bubbles moving inside a microfluidic channel beneath the DUET display.

FIG. 5B is a set of photographs of the dynamic bubble detection setup with (bottom) and without (top) a DUET display mounted on top.

FIG. 5C is a graph showing EL intensity as a function of time, with inset photographs of an air bubble passing through the microfluidic channel.

FIG. 5D is a schematic diagram of dynamic motion tracking achieved by movement of a SAW device in the xy plane underneath a 3×3 DUET display array.

FIG. 5E is a set of EL photographs showing dynamic motion tracking achieved by movement of a SAW device in the xy plane underneath a 3×3 DUET display array.

FIG. 6A is a schematic diagram of the trapped bubble detection setup (top) and the positions of bubbles inside the microfluidic channels (bottom).

FIG. 6B is a set of photographs of the experimental setup (left), the DUET display array (center), and the microfluidic channels beneath the display (right).

FIG. 6C is a graph showing the acoustic wave transmission coefficient (T) for each pixel.

FIG. 6D is an EL photograph in which white dotted squares indicate the pixels where the bubbles are positioned.

FIG. 6E is a graph showing the EL intensity of each pixel during detection.

FIG. 7 is a schematic diagram showing the fabrication procedure for each component and layer of the DUET display.

FIG. 8 is a set of cross-sectional scanning electron microscopy (SEM) images and energy dispersive X-ray (EDX) elemental maps of the emissive layer of the DUET display without PDMS coating and PVA protective layer (top) and with both PDMS coating and PVA protective layer (middle), together with a table summarizing the elemental compositions from EDX analysis (bottom).

FIG. 9 is a set of surface SEM images and EDX elemental maps comparing the surface structure of the emissive layer of the DUET display with and without PDMS coating and PVA protective layer.

FIG. 10A is an optical microscopy (OM) image of carbon black microspheres suspended in n-hexadecane.

FIG. 10B is an SEM image of the microspheres drop-cast on a glass substrate.

FIG. 11A is a graph showing luminance-voltage (L-V) characteristics of the DUET display emissive layer using P(VDF-TrFE-CFE) or PDMS as the polymer matrix.

FIG. 11B is a graph showing L-V characteristics of the DUET display with and without PDMS coating.

FIG. 11C is a graph showing L-V characteristics of the DUET display with and without a PVA protective layer.

FIG. 12A is a graph showing L-V characteristics of DUET displays fabricated at different spin-coating speeds (rpm).

FIG. 12B is a graph showing L-V characteristics of DUET displays fabricated with different ZnS:Cu phosphor-to-polymer ratios (ZnS/Polymer).

FIG. 12C is a graph showing L-V characteristics of DUET displays fabricated with different polymer concentrations in the composite solution (Polymer/MEK).

FIG. 13A is a graph showing L-V characteristics of DUET displays with different silicone chamber heights.

FIG. 13B is a graph showing L-V characteristics of DUET displays with different gaps between the ITO electrodes.

FIG. 13C is a graph showing L-V characteristics of DUET displays with different particle concentrations in the conductive fluid.

FIG. 14A is a schematic diagram of a DUET display using aluminum (Al) as a fixed conductive bridge.

FIG. 14B is a graph showing luminance-voltage (L-V) characteristics and an EL photograph of the DUET display with an Al bridge area of 6.5 mm×25 mm.

FIG. 14C is a graph showing luminance-voltage (L-V) characteristics and an EL photograph of the DUET display with an Al bridge area of 6.5 mm×6.5 mm.

FIG. 15 is a schematic diagram of DUET displays with (left) and without (right) conductive bridges and their corresponding equivalent electrical circuit models.

FIG. 16A is a schematic diagram of the setup for real-time in situ observation of particle self-assembly by optical microscopy (OM).

FIG. 16B is a graph showing the transmittance of the optimized emissive layer (original) and the emissive layer modified for imaging purposes.

FIG. 16C is a set of photographs comparing the optimized emissive layer (original) and the emissive layer modified for imaging purposes.

FIG. 17 is a set of zoomed-in optical microscopy images of dendrites and conductive bridges formed at various DEP force intensities, captured by real-time in situ observation.

FIG. 18A is a set of finite-element analysis results showing the electric field distribution of the DUET display at different operating voltages (frequency: 10 kHz).

FIG. 18B is a graph showing calculated DEP forces directly beneath the top cover of the chamber (distance=0 μm) at the position nearest to the ITO electrode edges.

FIG. 19 is a graph showing calculated DEP forces as a function of distance from the top cover of the chamber (chamber height: 400 μm), indicating the trapping radius at each operating voltage.

FIG. 20 is a graph showing EL intensity as a function of time under different operating voltages.

FIG. 21 is an enlarged graph showing L-V characteristics of the DUET display at various DEP frequencies, focused on the operating voltage range below 250 V and luminance below 100 cd m⁻².

FIG. 22 is a set of EL photographs of the DUET display in On-mode captured under various combinations of operating voltage (horizontal axis) and frequency (vertical axis).

FIG. 23 is a schematic diagram of particle movements under different ACP force intensities and the mechanism by which the conductive bridges collapse under ACP force, causing the DUET display to enter Off-mode.

FIG. 24A is a set of finite-element analysis results showing the acoustic pressure field distribution inside the chamber of the DUET display at different input voltages of the SAW device.

FIG. 24B is a graph showing calculated acoustophoretic (ACP) forces (primary acoustic radiation forces) derived from the finite-element analysis results of FIG. 24A.

FIG. 25A is a set of EL photographs of the DUET display in Off-mode captured under various ACP force intensities (horizontal axis) and DEP force intensities (vertical axis).

FIG. 25B is a graph showing EL change (ΔL/Lₒ) corresponding to the EL photographs of FIG. 25A.

FIG. 25C is a graph showing contrast ratio corresponding to the EL photographs of FIG. 25A.

FIG. 25D is a graph showing EL area corresponding to the EL photographs of FIG. 25A.

FIG. 25E is a graph showing On/Off area ratio corresponding to the EL photographs of FIG. 25A.

FIG. 26A is a set of EL photographs of the DUET display in Off-mode captured under various ACP force intensities (horizontal axis) and DEP frequencies (vertical axis).

FIG. 26B is a graph showing EL change corresponding to the EL photographs of FIG. 26A.

FIG. 26C is a graph showing contrast ratio corresponding to the EL photographs of FIG. 26A.

FIG. 26D is a graph showing EL area corresponding to the EL photographs of FIG. 26A.

FIG. 26E is a graph showing On/Off area ratio corresponding to the EL photographs of FIG. 26A.

FIG. 27A is a schematic diagram of a DUET display with a silicone chamber height of 100 μm.

FIG. 27B is a set of EL photographs of the DUET display of FIG. 27A in Off-mode, showing EL emission under different ACP force intensities obtained by varying the input voltage of the SAW device.

FIG. 28A is a schematic diagram of a DUET display with a conductive fluid concentration of 8 wt %.

FIG. 28B is a set of Off-mode EL photographs of the DUET display of FIG. 28A showing EL emission under different ACP force intensities.

FIG. 29 is a schematic diagram of the DUET display and SAW device in which the SAW device generates acoustic waves with a phase difference (Ap) (left), together with EL photographs of the DUET display under phase control showing subtle changes in Off-mode emission (right).

FIG. 30A is a set of schematic diagrams of the DUET display together with SAW devices generating acoustic waves of 280 μm (left) and 140 μm (right) wavelengths, respectively.

FIG. 30B is a graph showing EL change of the DUET display under different ACP intensities (SAW voltage) for acoustic waves of 140 μm wavelength.

FIG. 30C is a graph showing EL area of the DUET display under different ACP intensities (SAW voltage) for acoustic waves of 140 μm wavelength.

FIG. 31 is a set of optical microscopy (OM) images showing real-time in situ observation of particle self-assembly of carbon nanoparticles (top), nanofibers (middle), and microfibers (bottom) under DEP and ACP forces, individually and in combination.

FIG. 32 is a set of optical microscopy (OM) images showing real-time in situ observation of conductive bridges formed by DEP force (left), conductive bridges disrupted by ACP force (center), and conductive bridge reconstruction after removal of the acoustic pressure field (right).

FIG. 33 is a graph showing the S-parameter (|S₁₁|) of the SAW device (black line) and EL change of the DUET display (blue bars) under different input frequencies of the SAW device, for a conductive fluid using dodecane as the medium.

FIG. 34 is a schematic diagram of the fabrication procedure for a 3×3 array of DUET displays.

FIG. 35 is a graph showing EL intensity of the DUET display as a function of time (frames, 10 fps) depending on whether the BAW transducer is in operation.

FIG. 36 is a set of optical photographs of the EL emission state of the DUET display captured at successive frames during BAW transducer operation.

### DETAILED DESCRIPTIONS

Hereinafter, embodiments of the present invention will be described in detail with reference to the accompanying drawings. The present invention may be embodied in many different forms and should not be construed as limited to the specific embodiments set forth herein; rather, these embodiments are provided so that this disclosure will be thorough and complete. Like reference numerals are used to refer to like elements throughout the description of the drawings. In the accompanying drawings, the dimensions of structures are exaggerated relative to their actual size for clarity of the present invention.

The terminology used herein is for the purpose of describing particular embodiments only and is not intended to limit the present invention. The singular forms are intended to include the plural forms as well, unless the context clearly indicates otherwise. In the present application, terms such as “comprise” or “have” are intended to designate the presence of features, numbers, steps, operations, elements, or combinations thereof described in the specification, and are not to be understood as precluding the possibility of the presence or addition of one or more other features, numbers, steps, operations, elements, or combinations thereof. In the context of the present specification, terms such as “about” may mean approximately ±1%, approximately ±2%, approximately ±3%, approximately ±4%, approximately ±5%, approximately ±6%, approximately ±7%, approximately ±8%, approximately ±9%, or approximately ±10% of the numerical value described in the specification.

In addition, descriptions relating to one aspect of the present invention may be applied equally or similarly to identical or similar configurations or terms in descriptions relating to other aspects.

Unless otherwise defined, all terms used herein, including technical and scientific terms, have the same meaning as commonly understood by one of ordinary skill in the art to which the present invention belongs. Terms defined in commonly used dictionaries should be interpreted as having meanings consistent with those in the context of the relevant technology, and should not be interpreted in an idealized or overly formal sense unless explicitly defined in the present application.

The dual-sensing alternating current electroluminescent device according to an embodiment of the present invention may comprise: an acoustic wave generating unit comprising a substrate, a first electrode formed adjacent to the substrate, and a second electrode formed adjacent to the substrate and spaced apart from the first electrode; a matrix unit positioned on the acoustic wave generating unit and comprising a chamber capable of receiving a fluid therein, a fluid received within the chamber, and conductive particles dispersed in the fluid; an electroluminescent layer positioned on the matrix unit and configured to emit light when a voltage is applied thereto; a third electrode positioned on the electroluminescent layer and formed coplanar with the electroluminescent layer; and a fourth electrode positioned on the electroluminescent layer, formed coplanar with the electroluminescent layer, and spaced apart from the third electrode.

The role of the first electrode and the second electrode is to function as an electrode pair formed on the substrate to generate acoustic waves. These electrodes may be arranged in an interdigitated configuration, and when a voltage of a specific frequency is applied, they may induce a stable acoustic wave within the substrate. The standing acoustic wave thus formed may be a bulk acoustic wave or a surface acoustic wave. The generated acoustic wave may reach the matrix unit positioned above and exert an acoustic radiation force on the conductive particles within the fluid, thereby inducing rearrangement or migration of the particles. In addition, such acoustic waves may cause particles to concentrate at specific positions (nodes or antinodes) within the acoustic field, thereby serving as a mediator for controlling the light emission state of the device.

In one embodiment, the dual-sensing alternating current electroluminescent device may further comprise an acoustic wave power supply configured to apply a voltage to the first electrode and the second electrode to form a standing acoustic wave in the matrix unit. The role of the acoustic wave power supply is to apply a predetermined high-frequency voltage to the first electrode and the second electrode to generate a standing acoustic wave on the substrate, and thereby to form a standing acoustic wave within the fluid in the matrix unit. Such acoustic waves may exert an acoustic radiation force on the conductive particles in the fluid, helping the particles to migrate toward specific positions (e.g., nodes or antinodes). This process may be useful for controlling the spatial distribution of particles or for disassembling previously formed conductive bridges, and may provide the physical mechanism necessary for controlling light emission in response to external stimuli.

In one embodiment, the acoustic wave power supply may provide a frequency range including a resonant frequency and/or an antiresonant frequency within a frequency range of about 13 to 15 MHz. If the frequency is too low, the wavelength of the generated acoustic wave may become excessively large, weakening the driving force for particle migration within the matrix unit. This may reduce the spatial resolution of the acoustic radiation force, causing the particles to fail to concentrate at well-defined nodes or antinodes, or reducing the efficiency of disassembly of particle assemblies. If the frequency is too high, the wavelength of the acoustic wave becomes shorter, and the inter-node distance relative to particle size becomes too small, which may prevent stable concentration of particles or result in non-uniform distribution.

The frequency at which a standing acoustic wave can be generated refers to the frequency range under which the surface acoustic wave emitted from the acoustic wave power supply forms a stationary pattern within the medium through reflection and interference. This frequency is closely related to the structural characteristics of the acoustic wave device (e.g., electrode spacing, piezoelectric substrate material), and is generally likely to be formed at the resonant frequency or antiresonant frequency. At such frequencies, the acoustic radiation force acting on the particles exhibits a spatially periodic distribution, and the conditions under which particles can stably migrate or align toward specific positions are satisfied.

In one embodiment, the first electrode and the second electrode may be formed in an interdigitated configuration. An interdigitated electrode refers to a structure in which two electrodes are arranged in a comb- or finger-like configuration that interdigitates with each other, forming alternating electrode structures on the same plane. By forming the first electrode and the second electrode as interdigitated electrodes, conditions for generating a more stable and uniform surface acoustic wave (SAW) on the substrate may be established, and the standing acoustic wave may be efficiently transmitted to the fluid within the matrix unit.

The role of the chamber is to provide a space for stably accommodating the conductive particles and non-polar fluid, and to form a physical environment in which the particles can freely migrate or rearrange in response to external stimuli. The chamber serves as the operational region where particle manipulation substantially occurs, and it is preferable that the chamber maintains sufficient volume and hermeticity to allow the particles to respond when an electric field or acoustic field is applied.

The role of the fluid is to maintain the conductive particles in a dispersed state while providing a medium that enables them to respond sensitively to external electric fields or acoustic fields. In particular, a non-polar fluid may suppress inter-particle aggregation and influence the distribution of induced charges formed on particle surfaces, thereby helping to control the dielectrophoretic phenomenon more precisely.

The role of the conductive particles is to function as a mediator that migrates or aligns in response to an electric field to form an electrical pathway between the electrodes, thereby enabling current to flow through the electroluminescent layer. When an external electric field is applied, these particles form a bridge that lowers resistance, and under acoustic stimulation, the structure is disassembled and the particles return to a non-conductive state, exhibiting reconfigurability. This characteristic enables dynamic control of the light emission state of the device, and consequently enables the realization of visual feedback in response to external stimuli.

The overall role of the matrix unit is to serve as the central space where interactions among the fluid, conductive particles, electric field, and acoustic field occur, providing a physical and functional platform for realizing the dual-sensing characteristics. This region is one in which multiple functions-including fluid retention, particle response, and electric field transmission-operate in combination, and may constitute the core structure that determines the sensing and display performance of the device.

The role of the electroluminescent layer is to function as a light-emitting region that emits light in response to an external alternating current voltage when an electric field is applied, depending on the arrangement state of the conductive particles. This layer has a structure in which phosphors such as ZnS:Cu are dispersed within a polymer matrix, and since an effective electric field is formed only when a conductive bridge is established by the particles, whether light emission occurs may vary depending on the dynamic changes within the matrix.

The principle by which the electroluminescent layer emits light is based on the electroluminescent phenomenon in which electrons within the phosphor are excited when a high-frequency alternating current voltage is applied, and subsequently emit photons upon returning to the ground state. However, such light emission requires that a sufficiently strong electric field be applied, which can only be realized when the conductive particles form a conductive bridge under specific conditions within the matrix. The fact that light emission is selectively induced by the electric field distribution in this manner means that light emission and extinction can be repeated depending on whether the conductive particles are assembled, and may contribute to the real-time visual representation of the device state in response to input signals.

The role of the third electrode and the fourth electrode is to be positioned at both ends of the electroluminescent layer to apply an alternating current voltage and generate an electric field. These electrodes are disposed facing each other on the upper surface of the emissive layer, and a high-frequency power source supplied from outside acts between them to form an electric field within the emissive layer. However, this electric field can effectively reach the emissive layer only when an electrical pathway formed by the conductive particles is present. Accordingly, the third and fourth electrodes do not merely function as driving electrodes, but may act as an interactive structure that determines whether light emission occurs in conjunction with the state of particles within the matrix.

In one embodiment, the dual-sensing alternating current electroluminescent device may further comprise an alternating current power supply configured to apply an alternating current voltage to the third electrode and the fourth electrode. The role of the alternating current power supply is to apply an alternating current voltage between the third electrode and the fourth electrode, thereby forming a high-frequency electric field within the electroluminescent layer and inducing excitation of the phosphor particles through this electric field. However, for the electroluminescent layer itself to emit light, the conductive particles must form a conductive bridge within the matrix unit, and the alternating current power supply can effectively induce light emission only when this condition is satisfied.

In one embodiment, the acoustic wave power supply may supply power to an acoustic wave device comprising two interdigital transducers (IDTs). Thereby, a high-frequency alternating current signal is applied between the two interdigital transducers (IDTs) on the acoustic wave device, and a surface acoustic wave may be generated in a piezoelectric substrate such as lithium niobate. Such a surface acoustic wave may form a standing acoustic wave with a certain periodicity through reflection and interference, and this standing acoustic wave may be transmitted to the fluid in the matrix unit positioned above, exerting an acoustic radiation force on the conductive particles.

In one embodiment, the IDTs may be formed of aluminum on a LiNbO₃ substrate. The advantage of the substrate is that it has excellent piezoelectric properties and can generate surface acoustic waves with high conversion efficiency in response to externally applied high-frequency electrical signals. In particular, the LiNbO₃ substrate has a high electromechanical coupling coefficient, enabling the generation of strong acoustic output even under the same input conditions, making it well-suited for SAW- or BAW-based devices. Furthermore, by selecting a specific cut orientation (e.g., 128° Y-cut), the phase velocity and temperature coefficient characteristics along the propagation direction can be adjusted, which is advantageous for realizing desired resonant frequency or temperature response characteristics.

In one embodiment, the conductive particles may comprise carbon black microspheres. The advantage of carbon black is that it has excellent electrical conductivity while potentially bearing various functional groups on the particle surface, enabling sensitive response to external electric fields. In addition, carbon black has an amorphous structure that facilitates electrical connectivity between particles, and exhibits high dispersion stability, allowing it to spread uniformly within the fluid.

The advantage of conductive particles in the form of microspheres is that the spherical structure reduces inter-particle friction and physical entanglement within the fluid, enabling rapid rearrangement or migration in response to external stimuli. Such a morphology may contribute to increasing the response speed of particles when dielectrophoretic force or acoustic radiation force is applied, and may also help minimize structural damage during repeated assembly and disassembly processes.

In one embodiment, the conductive particles may comprise carbon black microspheres having a diameter of about 2 to 12 μm. If the conductive particles are too small, the physical displacement in response to external electric fields or acoustic fields may be limited, and thermal fluctuations such as Brownian motion may dominate over the intended inter-particle interactions. This may result in unstable concentration of particles at intended positions, or in the formation of an unstable conductive bridge. If the conductive particles are too large, their mobility within the fluid decreases, and there may be limitations in rapidly migrating to desired positions in response to dielectrophoretic force or acoustic radiation force. In particular, the dynamic responsiveness of the particles may be reduced by spatial constraints of the chamber or the viscosity of the fluid, which may affect the formation time or disassembly efficiency of the conductive bridge.

In one embodiment, the fluid may be a non-polar fluid. The advantage of a non-polar fluid as the medium in which conductive particles are dispersed is that it suppresses electrostatic aggregation between particles and enables more sensitive induction of migration by dielectrophoresis. A non-polar medium has a low dielectric constant, which allows the induced charge distribution on the particle surface to be clearly formed, and this may be advantageous for precisely controlling the migration path of particles when an external electric field is applied.

In one embodiment, the non-polar fluid may comprise n-hexadecane. The advantage of n-hexadecane is that it maintains a stable liquid state at room temperature while having low volatility, thereby reducing concerns about evaporation or viscosity changes within a hermetically sealed structure over extended periods of time. Since this fluid has non-polar characteristics, unnecessary interference in electrical interactions with conductive particles is minimal, and the response characteristics of the particles to dielectrophoretic force or acoustic radiation force may be more clearly manifested.

In one embodiment, the electroluminescent layer may comprise ZnS:Cu. The characteristic of ZnS:Cu is that electrons can be excited when a high-frequency alternating current electric field is applied from outside, and visible light may be emitted upon returning to the ground state. ZnS doped with a small amount of Cu forms new energy levels within the bandgap, which may allow light emission to occur at lower electric fields.

In one embodiment, the ZnS:Cu may have an average particle diameter of about 20 to 30 μm. If the luminescent particles ZnS:Cu are too small, the surface-area-to-volume ratio increases, which may facilitate inter-particle aggregation and make it difficult to achieve uniform dispersion within the emissive layer. This may result in non-uniform delivery of the electric field to the particles or a reduction in luminescent efficiency. If the luminescent particles ZnS:Cu are too large, dispersibility within the polymer matrix may decrease, causing the particles to settle or agglomerate. This may lead to non-uniform application of the electric field to the phosphors, resulting in light emission occurring only in certain regions and causing output imbalance.

In one embodiment, the electroluminescent layer may be a composite film comprising ZnS:Cu phosphors and a polymer matrix. Thereby, the phosphor particles may be stably dispersed within the polymer matrix in the emissive layer, forming a structure that is effectively excited and emits light upon application of an external electric field.

In one embodiment, the advantage of the polymer matrix comprising P(VDF-TrFE-CFE) is that it may exhibit a combination of high dielectric constant, excellent flexibility, and responsiveness to electric fields. In particular, this polymer may have a structure capable of delivering a sufficient electric field to the phosphors even at low electric field strengths, and the dielectric properties may be stably maintained under repeated voltage application conditions.

In one embodiment, the thickness of the electroluminescent layer may be about 20 μm. Thereby, a physical balance may be achieved in which the phosphor particles are sufficiently incorporated while the external electric field can be effectively applied. If the layer is too thin, dispersion of the particles may become non-uniform or the electric field may not be sufficiently transmitted; conversely, if the layer is too thick, voltage loss or reduced luminescent efficiency may occur.

In one embodiment, the weight ratio of ZnS to polymer matrix in the electroluminescent layer may be about 4:1 to 13:1. If the electroluminescent material is present in excess, interfacial bonding with the polymer matrix may become incomplete, and aggregation or sedimentation of particles may occur, reducing the uniformity of the emissive layer. If the electroluminescent material is insufficient, the amount of phosphors that can be excited by the externally applied electric field becomes inadequate, and the overall luminescent intensity may be significantly reduced.

In one embodiment, when an alternating current voltage is applied to the third electrode and the fourth electrode and no standing acoustic wave is applied to the matrix unit through the first electrode and the second electrode, the conductive particles in the fluid may migrate by dielectrophoresis to form a conductive bridge connecting the third electrode and the fourth electrode in an upper portion of the fluid, thereby inducing light emission from the electroluminescent layer.

The reason the electroluminescent layer emits light only when the conductive bridge is formed is that, for the alternating current voltage applied between the third electrode and the fourth electrode to be transmitted throughout the electroluminescent layer, an electrical pathway must be formed through the matrix unit. Although the matrix unit, consisting of fluid and particles, is in a state close to electrical insulation, when the conductive particles are aligned by dielectrophoretic force to form a bridge-type pathway, the potential difference between the electrodes can effectively reach the electroluminescent layer.

By utilizing this principle, light emission from the electroluminescent layer can also be extinguished. In one embodiment, when a standing acoustic wave is applied through the first electrode and the second electrode while the conductive bridge is formed, the conductive particles may migrate toward nodes of the standing acoustic wave and the conductive bridge may be disrupted, resulting in extinction of light emission from the electroluminescent layer. Thereby, the conductive bridge is physically disassembled, the electrical connection between the electrodes is interrupted, and an effective electric field is no longer applied to the electroluminescent layer. As a result, the phosphor particles cannot be excited, and consequently the device may transition to a state in which light emission is extinguished. This mechanism may serve as a means of actively controlling light emission in response to external stimuli, and may be utilized to visually represent changes in the external environment or the detection of specific conditions.

The advantage of the dual-sensing alternating current electroluminescent device according to the embodiments of the present invention described above lies in the fact that it has a structure capable of selectively responding to two distinct physical stimuli, namely electric fields and acoustic fields. By implementing the dielectrophoretic assembly of conductive particles and their disassembly by acoustic radiation force in a repeatable manner within a single matrix, the device may be capable of visually confirming the presence or sequence of external stimuli.

Meanwhile, the temperature sensing device according to an embodiment of the present invention may comprise a dual-sensing alternating current electroluminescent device comprising: an acoustic wave generating unit comprising a substrate, a first electrode formed adjacent to the substrate, and a second electrode formed adjacent to the substrate and spaced apart from the first electrode; a matrix unit positioned on the acoustic wave generating unit and comprising a chamber capable of receiving a fluid therein, a fluid received within the chamber, and conductive particles dispersed in the fluid; an electroluminescent layer positioned on the matrix unit and configured to emit light when a voltage is applied thereto; a third electrode positioned on the electroluminescent layer and formed coplanar with the electroluminescent layer; a fourth electrode positioned on the electroluminescent layer, formed coplanar with the electroluminescent layer, and spaced apart from the third electrode; an acoustic wave power supply configured to apply a voltage to the first electrode and the second electrode to form an acoustic wave in the matrix unit; and an alternating current power supply configured to apply an alternating current voltage to the third electrode and the fourth electrode.

In one embodiment, the acoustic wave formed by the acoustic wave power supply may be a bulk acoustic wave.

In one embodiment, the acoustic wave formed by the acoustic wave power supply may be a standing acoustic wave.

In one embodiment, the temperature sensing device may be configured such that when an alternating current voltage is applied to the third electrode and the fourth electrode and no standing acoustic wave is applied to the matrix unit through the first electrode and the second electrode, the conductive particles in the fluid migrate by dielectrophoresis to form a conductive bridge connecting the third electrode and the fourth electrode in an upper portion of the fluid, thereby inducing light emission from the electroluminescent layer. In one embodiment, when a standing acoustic wave is applied through the first electrode and the second electrode while the conductive bridge is formed, the conductive particles may migrate toward nodes of the standing acoustic wave and the conductive bridge may be disrupted, resulting in extinction of light emission from the electroluminescent layer.

In one embodiment, the temperature sensing device may further comprise a controller configured to adjust a frequency of the acoustic wave power supply. The role of the controller is to actively modify the resonance conditions of the surface acoustic wave formed on the substrate by adjusting the frequency of the voltage applied to the acoustic wave power supply. Through this, it is possible to control whether a standing acoustic wave is formed, or to precisely control the migration behavior of the conductive particles by adjusting the wavelength and intensity of the acoustic wave. In particular, when the acoustic transmission properties of the fluid in the matrix unit change due to external temperature variations, the resonance conditions at a specific frequency may shift, and the controller may help detect such frequency changes or set corresponding driving conditions.

In one embodiment, the temperature sensing device may sense temperature by utilizing a shift in the frequency at which the acoustic wave power supply is capable of forming an acoustic wave to disrupt the conductive bridge, the shift occurring when acoustic transmission properties of the fluid change due to a variation in temperature. For example, when the temperature rises, the density or viscosity of the fluid in the matrix unit may decrease, and as a result, the propagation speed or attenuation characteristics of the acoustic wave may change. Such changes may alter the conditions under which a standing acoustic wave was previously formed at a specific frequency, and new resonance conditions may potentially be formed at frequencies where standing acoustic waves were not previously generated. As another example, when the temperature decreases, the viscosity and acoustic impedance of the fluid may increase, and the standing acoustic wave may not be sufficiently formed under the existing frequency conditions, or the acoustic radiation force exerted on the particles may be weakened. These effects will become apparent from the embodiments described below.

The advantage of the temperature sensing device according to the embodiments of the present invention described above lies in the ability to visually recognize the temperature state through light emission without requiring a separate temperature-sensing material or sensor, by utilizing the fact that the acoustic transmission properties of the fluid naturally change with temperature. In particular, since the phenomenon is based on the shift of the resonant frequency of the standing acoustic wave with temperature, there is the possibility of reflecting very sensitive and continuous temperature changes. Furthermore, since the assembly and disassembly of the conductive particles are directly linked to the ON/OFF state of light emission, real-time visual feedback is possible without complex circuitry or data processing.

Meanwhile, the temperature sensing method according to an embodiment of the present invention may comprise sensing temperature using the temperature sensing device according to the embodiment of the present invention.

Meanwhile, the foreign substance sensing device according to an embodiment of the present invention may comprise a dual-sensing alternating current electroluminescent device comprising: an acoustic wave generating unit comprising a substrate, a first electrode formed adjacent to the substrate, and a second electrode formed adjacent to the substrate and spaced apart from the first electrode; a matrix unit positioned on the acoustic wave generating unit and comprising a chamber capable of receiving a fluid therein, a fluid received within the chamber, and conductive particles dispersed in the fluid; an electroluminescent layer positioned on the matrix unit and configured to emit light when a voltage is applied thereto; a third electrode positioned on the electroluminescent layer and formed coplanar with the electroluminescent layer; a fourth electrode positioned on the electroluminescent layer, formed coplanar with the electroluminescent layer, and spaced apart from the third electrode; an acoustic wave power supply configured to apply a voltage to the first electrode and the second electrode to form an acoustic wave in the matrix unit; and an alternating current power supply configured to apply an alternating current voltage to the third electrode and the fourth electrode.

In one embodiment, the foreign substance sensing device may further comprise a fluid channel formed between the substrate and the matrix unit through which a second fluid passes. The role of the fluid channel is to form a pathway through which the second fluid—such as air bubbles or other fluid components—passing through the lower portion of the matrix unit can be controlled or detected. This channel serves as the medium through which the surface acoustic wave (SAW) travels before being transmitted to the conductive particles, and the propagation characteristics of the SAW or the intensity of the acoustic radiation force exerted on the particles may vary depending on the physical properties of the fluid present in the channel (e.g., density, acoustic impedance, viscosity). That is, in one embodiment, the dual-sensing alternating current electroluminescent device may be capable of sensing a foreign substance within the fluid channel.

In one embodiment, when an alternating current voltage is applied to the third electrode and the fourth electrode and no standing acoustic wave is applied to the matrix unit through the first electrode and the second electrode, the conductive particles in the fluid may migrate by dielectrophoresis to form a conductive bridge connecting the third electrode and the fourth electrode in an upper portion of the fluid, thereby inducing light emission from the electroluminescent layer. In one embodiment, when a standing acoustic wave is applied through the first electrode and the second electrode while the conductive bridge is formed, the conductive particles may migrate toward nodes of the standing acoustic wave and the conductive bridge may be disrupted, resulting in extinction of light emission from the electroluminescent layer.

In one embodiment, the foreign substance sensing device may sense a change in light emission intensity of the electroluminescent layer that occurs as a result of disruption and formation of the conductive bridge, the disruption and formation being caused by a change in whether the standing acoustic wave is formed, which in turn occurs when acoustic transmission properties of a material passing through the fluid channel change. In one embodiment, the foreign substance may be a substance other than the second fluid or an air bubble. This principle is based on the phenomenon whereby the propagation path and intensity of the surface acoustic wave generated from the substrate change as the acoustic transmission properties of the fluid or material passing through the fluid channel—such as density, compressibility, viscosity, or acoustic impedance—vary. When a foreign substance such as an air bubble or solid particle passes through the channel, acoustic transmission and reflection occur differently compared to the original second fluid, which may directly affect the amount of acoustic energy transmitted to the matrix unit above. This may cause the standing acoustic wave to not be stably formed, or conversely, may destabilize a previously formed acoustic field, consequently altering the state of maintenance or disruption of the conductive bridge, and causing the presence or intensity of light emission from the electroluminescent layer to change in real time. These phenomena will become apparent from the embodiments described below.

The advantage of the foreign substance sensing device according to the embodiments of the present invention described above lies in the fact that the light emission state of the electroluminescent layer can change in real time in response to changes in the physical properties of materials flowing through the fluid channel. In particular, when a material whose acoustic transmission properties are clearly distinct from those of the existing fluid—such as an air bubble or foreign substance—flows through the channel, the conditions for forming the standing acoustic wave change sensitively, and accordingly, whether the conductive bridge is maintained changes, resulting in an immediate response in the light emission state. This enables visual determination of the presence of foreign substances within the fluid based solely on visual signals, without the need for complex optical sensors or analytical equipment, and since the sensor does not directly contact the foreign substance, the durability of the device can also be ensured. Such a structure may find applicability across a wide range of fields including process monitoring based on microfluidics, bioanalysis, and environmental sensing.

Meanwhile, the foreign substance sensing method according to an embodiment of the present invention may comprise sensing a foreign substance using the foreign substance sensing device according to the embodiment of the present invention.

Meanwhile, in the motion tracking display according to an embodiment of the present invention, a plurality of the foreign substance sensing devices according to the embodiment of the present invention may be arranged, the fluid channels of the plurality of arranged foreign substance sensing devices may be fluidically connected to each other at least in part, and the movement of a foreign substance flowing within the fluidically connected fluid channels may be visually confirmable by light emission from the foreign substance sensing devices. By this configuration, when a foreign substance or air bubble moves within the fluid channel, only the foreign substance sensing devices arranged at the corresponding position selectively emit or extinguish light, enabling real-time visual tracking of the movement path of the foreign substance. Each sensing device independently controls its light emission state while sharing a fluidically connected pathway, thereby forming a structure that enables motion tracking within a single continuous flow. Through this, information such as the position, velocity, and direction of particles within the fluid can be intuitively obtained without external devices.

In one embodiment, the plurality of arranged foreign substance sensing devices may be arranged in an array. The term “array” as used herein refers to a structure in which a plurality of foreign substance sensing devices are regularly arranged in a two-dimensional or one-dimensional grid pattern, and each sensing device is a constituent unit that can be independently driven or operate in conjunction with others to indicate a response at a specific position. Such an array structure increases spatial resolution, enables precise position-based detection of dynamic changes occurring within the fluid, and may provide a basis for operating a large number of sensors in parallel on a single integrated platform.

The advantage of the motion tracking display according to the embodiments of the present invention described above lies in the ability to spatially visualize in real time the movement path of foreign substances or air bubbles within the fluid. As the plurality of foreign substance sensing devices arranged in an array respond to light emission at their respective positions, an observer can intuitively identify the direction, velocity, and position of the foreign substance flow simply from the light emission pattern, without the need for separate electronic equipment. Furthermore, since the structure of the device can be designed to be simple and flexible, it may be applicable to curved surfaces or miniaturized devices, and may find applicability across a wide range of fields including biological diagnostics, environmental sensors, and smart packaging, where intuitive information delivery based on a visual interface is required.

The following describes embodiments of the present invention. However, the embodiments described below represent only some embodiments of the present invention, and the scope of the present invention is not limited to the following embodiments.

### [Device Architecture and Dual-Mode Operation of DUET Display]

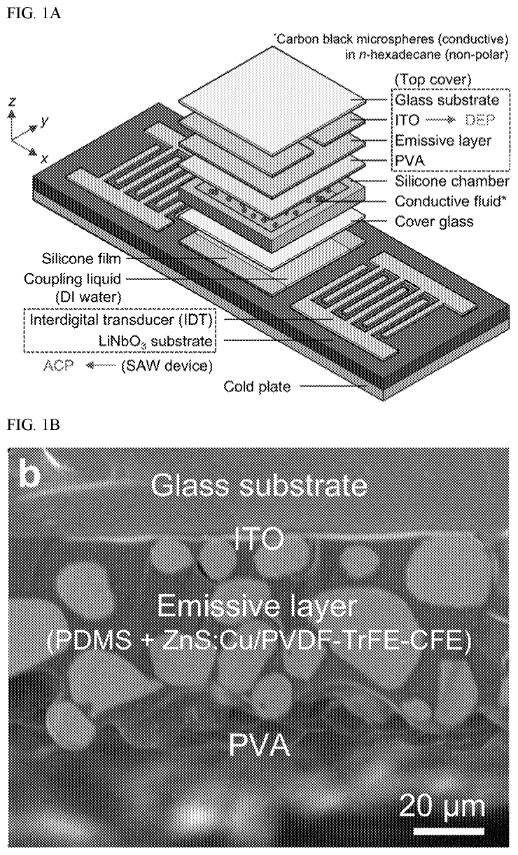

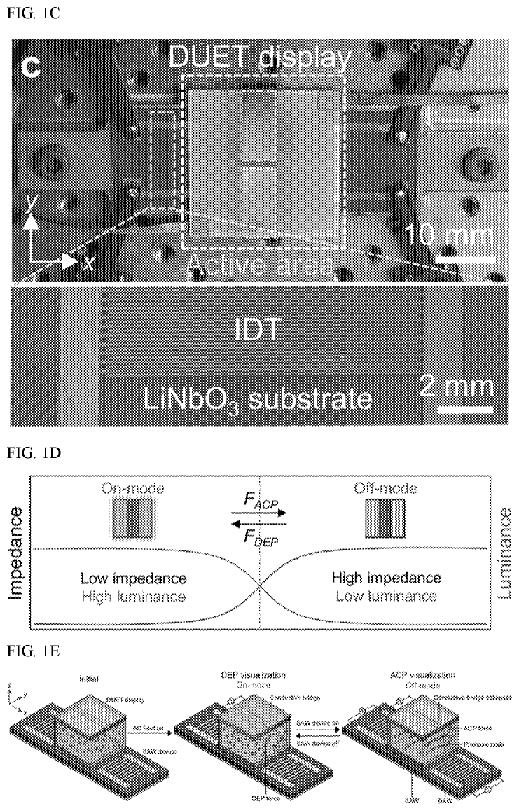

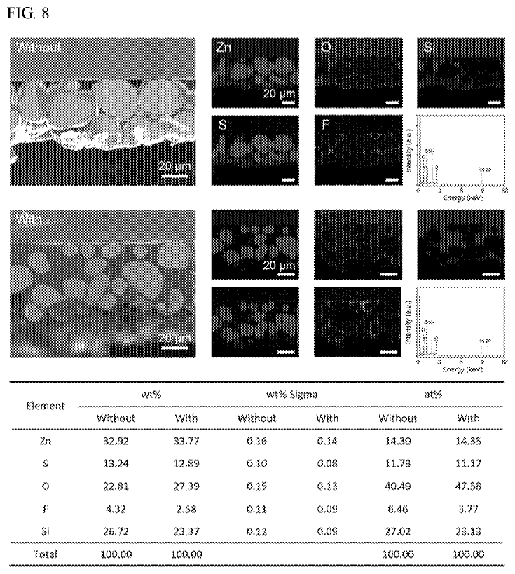

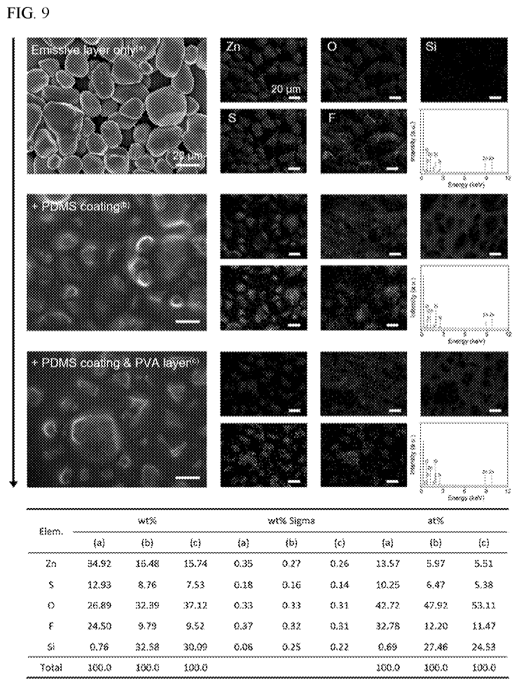

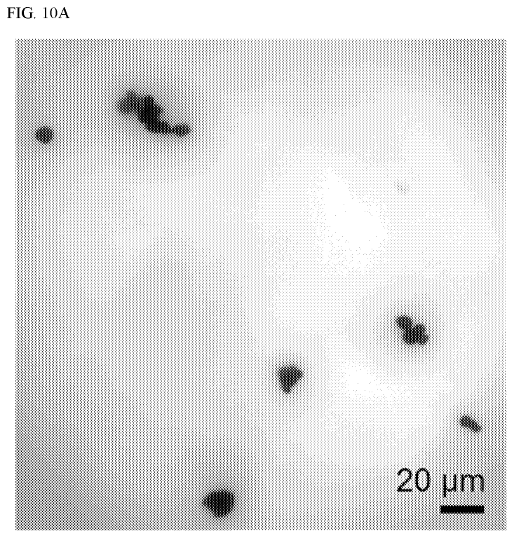

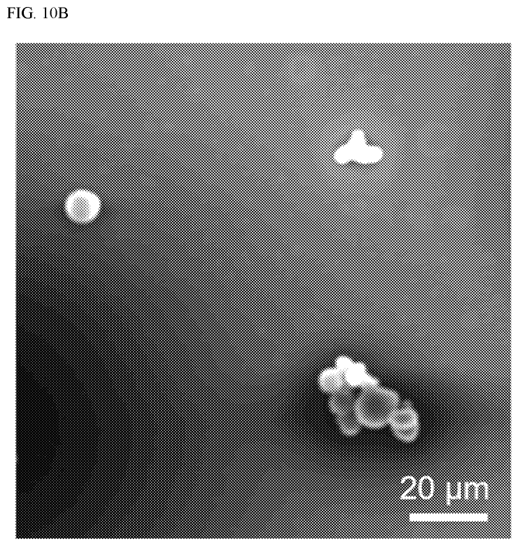

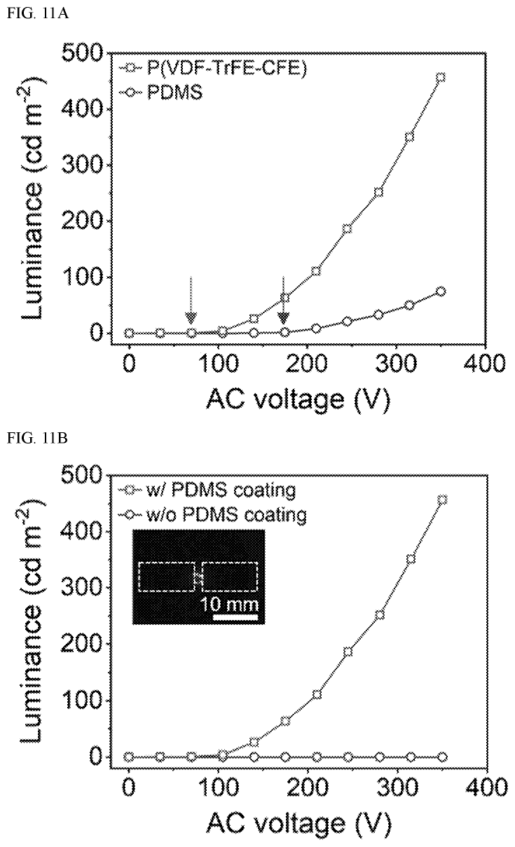

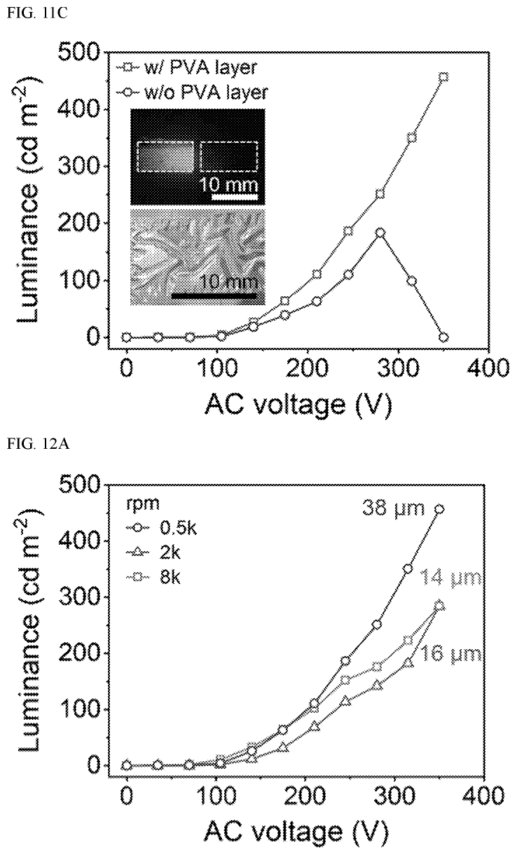

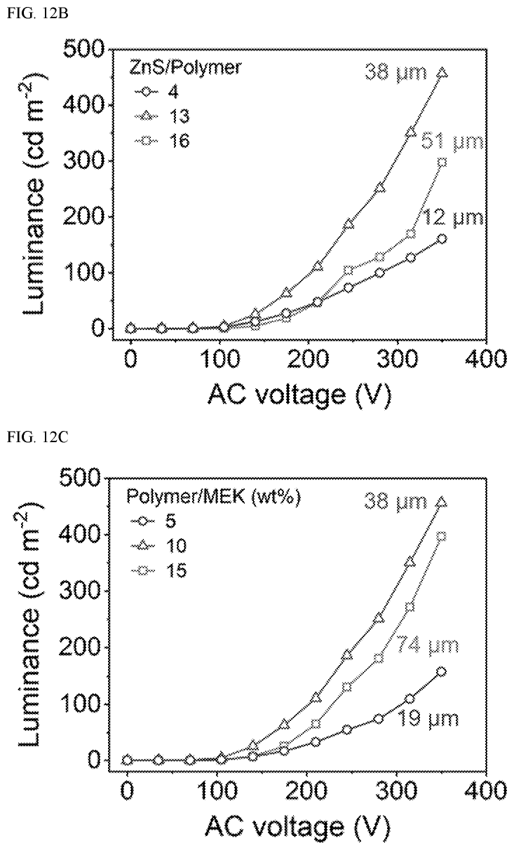

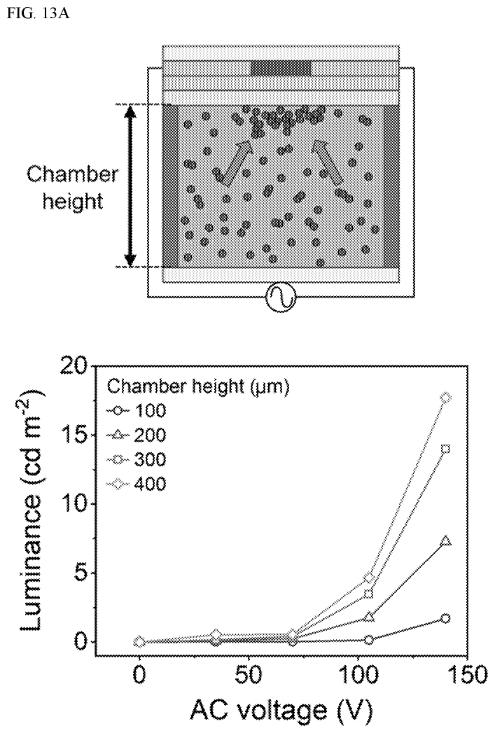

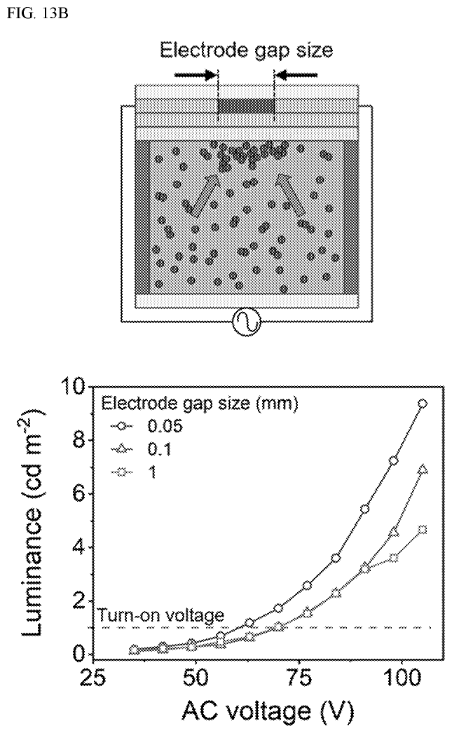

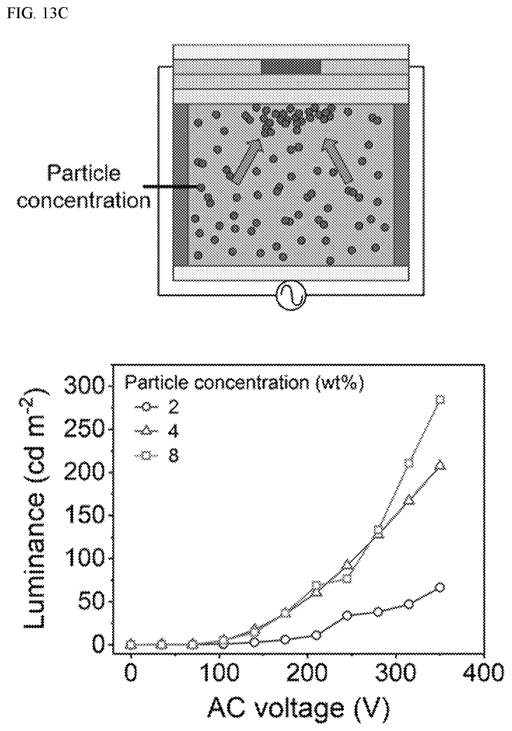

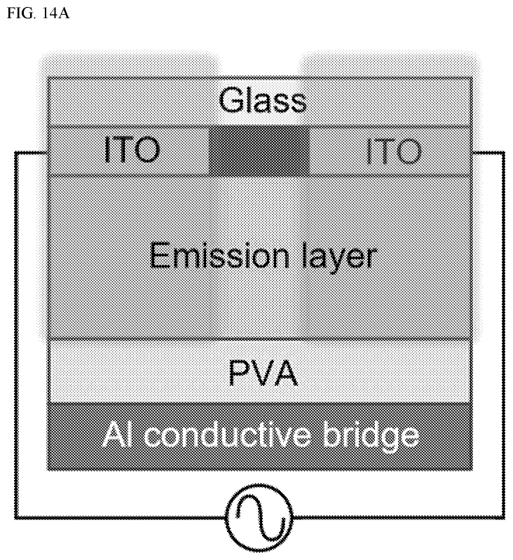

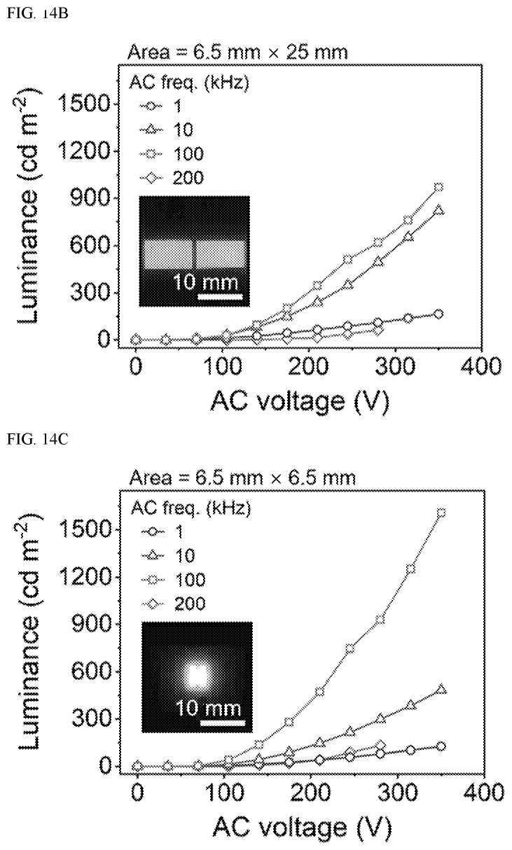

The device structure of the DUET display together with a SAW device is illustrated in FIG. 1A. A 38-μm-thick emissive layer consisting of ZnS:Cu phosphors (diameter, 25±5 μm) embedded in poly(vinylidene fluoride-co-trifluoroethylene-co-chlorofluoroethylene) [P(VDF-TrFE-CFE)] was fabricated by spin coating a composite solution on two coplanar transparent indium tin oxide (ITO) electrodes (gap, 1 mm) on a glass substrate (see FIG. 7). The high density of ZnS:Cu phosphors caused the composite to adopt a porous structure, which was confirmed by scanning electron microscopy (SEM) (see FIGS. 8 and 9). To prevent short-circuiting between the electrodes, the pores of the emissive layer were filled by spin coating a diluted polydimethylsiloxane (PDMS) solution on the emissive layer, which was confirmed by SEM together with energy dispersive X-ray (EDX) mapping of the constituent atomic elements (see FIGS. 8 and 9). In addition, a 120-nm-thick poly(vinyl alcohol) (PVA) layer was formed by spin coating a PVA solution on the emissive layer. The PVA layer serves to physically protect the PDMS coating from the conductive fluid composed of n-hexadecane, a non-polar medium. A 400-μm-thick rectangular silicone chamber attached to a cover glass was bonded together with the spin-coated glass substrate, which acts as a top cover of the chamber, by applying PDMS at the junction of the two components (see FIG. 7). The chamber was filled with a conductive fluid of 4.5 wt % carbon black dispersed in n-hexadecane (see FIG. 10), and was subsequently sealed with cover glasses. Luminance-voltage characteristics further confirmed that optimal performance is exhibited when the DUET display incorporates all the components of the emissive layer described above (see Supplementary Note 1, FIGS. 11 and 12). Additionally, various parameter studies of the display components were performed by varying the chamber height, electrode gap, and conductive fluid concentration, confirming the tunability of the DUET display under different sizes and conditions (see Supplementary Note 2 and FIGS. 13 and 14). The structure and components of the top cover were visualized by the SEM image in FIG. 1B. FIG. 1C shows a photograph of a fabricated DUET display mounted on a SAW device (top) and the IDT pattern of the SAW device (bottom) (see Methods).

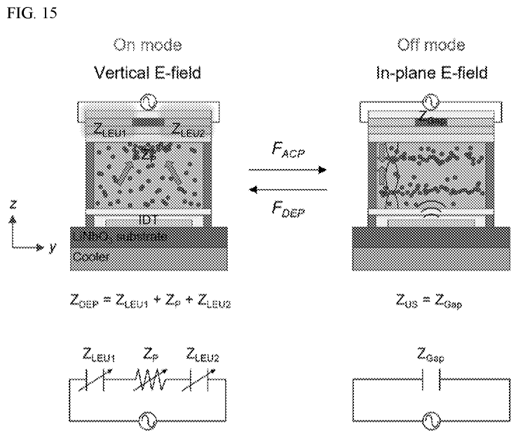

The modes of the DUET display can be controlled by the dielectrophoretic (DEP) force induced by an external AC electric field and the acoustophoretic (ACP) force induced by an acoustic wave, respectively (FIG. 1E). When the DEP force from the coplanar ITO electrodes is the dominant force acting on the carbon black microspheres, the microspheres migrate toward the gap between the electrodes and form conductive bridges beneath the top cover of the chamber. In this state, the total electrical impedance of the DUET display is lowered due to the high electrical conductivity of the bridges (see FIG. 1E, left, and FIG. 15, left). At this point, the electric field distribution is converted from in-plane to vertical, concentrating at the emissive layer, and field-driven electroluminescence (EL) from the ZnS:Cu phosphors occurs (On-mode, see FIG. 1F). The intensity of the EL emission depends on the percolation network density of the microspheres, which is determined by the magnitude of the DEP force. Accordingly, the DUET display can detect and visualize the magnitude of the DEP force through the transition from the Off-mode to the On-mode.

On the other hand, when the ACP force generated from the SAW device exceeds the DEP force, the microspheres are pushed toward the pressure nodes of the standing acoustic wave (see FIG. 1F, right, and FIG. 15, right). In this state, the chamber of the DUET display resembles a hybrid acoustic device in which both SAW and bulk acoustic wave (BAW) coexist, enabling the formation of a three-dimensional distribution pattern of the microspheres. In particular, since the pressure nodes created by the BAW are located at a certain distance from the top cover of the chamber, the microspheres become detached from the electrode gap. This leads to the disruption of the conductive bridges, and the electric field distribution reverts to being concentrated in the in-plane gap between the ITO electrodes, resulting in the Off-mode. As the ACP force becomes stronger, the total electrical impedance of the display increases, which can be visualized by the extent of the transition from the On-mode to the Off-mode (see FIG. 1E, right). The specific operation mechanisms of the DUET display will be described in detail below.

### [Working Principle and Characteristics of the DEP-Sensing On-Mode]

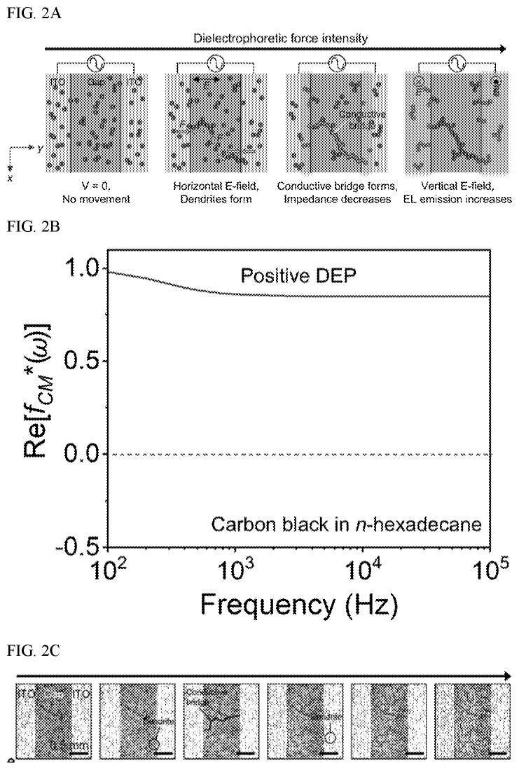

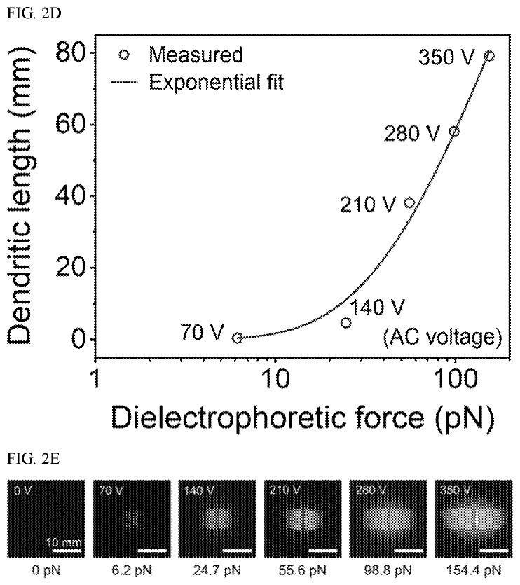

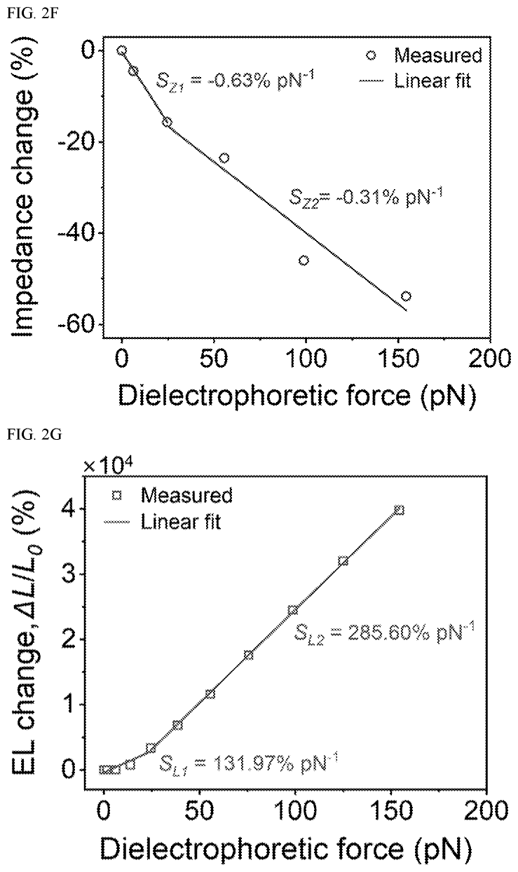

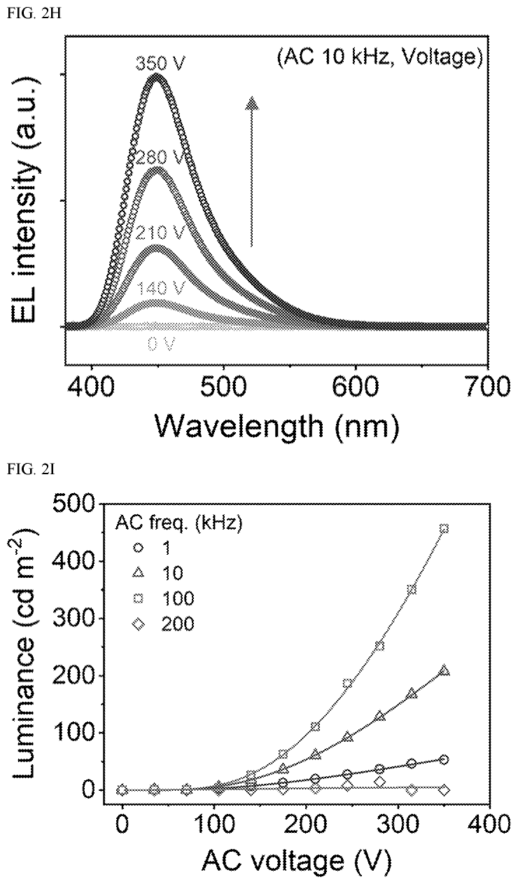

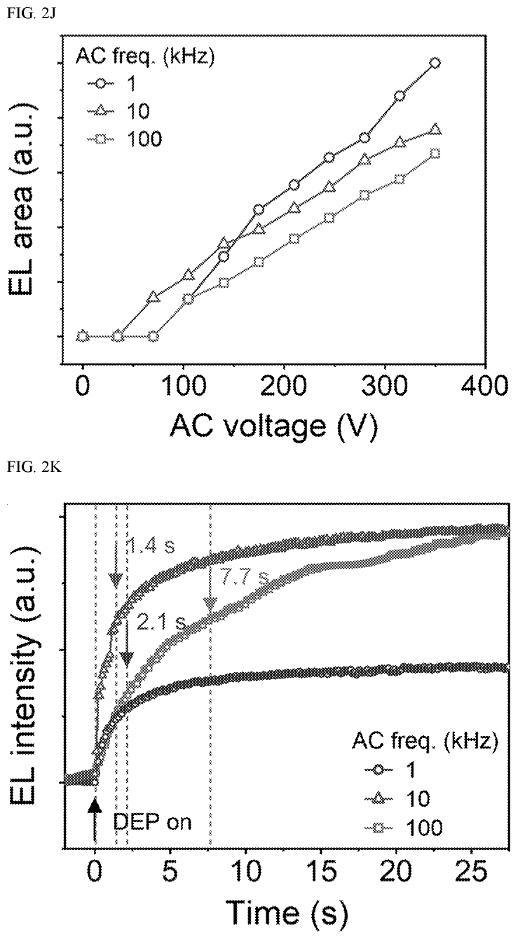

FIG. 2A illustrates the proposed states of particle self-assembly under different dielectrophoretic (DEP) force intensities at a given frequency. At the initial state, random Brownian motion acts on the suspended microspheres, and self-assembly near the electrode gap does not occur (leftmost of FIG. 2A). When a weak AC voltage is applied to the electrodes, the microspheres gather toward the edges of the electrodes where the electric field is maximized. In addition, the induced dipole moment of the microspheres causes electrostatic attraction between the particles, forming dendritic structures (chains of microspheres) beneath the top cover of the chamber. As the voltage increases, more particles are attached to the dendritic structures, and conductive bridges are formed across the electrode gap. In this state, the electric field is concentrated in the vertical direction. Therefore, as the voltage increases further, the microspheres also form dendritic structures beneath the ITO electrodes, and electroluminescence (EL) emission occurs (rightmost of FIG. 2A). At this point, the microspheres of the DUET display experience only positive DEP force from the external electric field, migrating toward regions of increasing electric field gradient. To validate this DEP characteristic of the DUET display, the real part of the Clausius-Mossotti factor Re[f*_{CM}(ω)] was calculated, where f*_{CM}(ω) is expressed as follows.

$${f}_{CM}^{*} ( ω ) = \frac{{ε}_{p}^{*} ( ω ) - {ε}_{m}^{*} ( ω )}{{ε}_{p}^{*} ( ω ) + 2 {ε}_{m}^{*} ( ω )} \qquad ( 1 )$$

where ε*p(ω) and ε* m(ω) are the complex dielectric permittivity of the particle and medium, respectively (see FIG. 2B, Supplementary Note 3, and Table 1). Particles experience positive DEP when Re[f*_{CM}(ω)] has a positive value, while negative DEP occurs for a negative value of Re[f*_{CM}(ω)], in which case particles are repelled toward the opposite direction. Because the electrical conductivity of the carbon microspheres is several orders of magnitude larger than that of n-hexadecane, a value close to unity is observed in the low-frequency regime near 10² Hz (see FIG. 2B). As the frequency increases above 103 Hz, Re[f*_{CM}(ω)] shows a slight decrease to 0.85, which is identical to the lower limit of Re[f*_{CM}(ω)], indicating that the value of Re[f*_{CM}(ω)] is always positive (see Supplementary Note 3). These results suggest that positive DEP always occurs in the carbon microspheres regardless of the intensity and frequency of the external electric field, and that the DUET display cannot be rewritten without the utilization of ACP force.

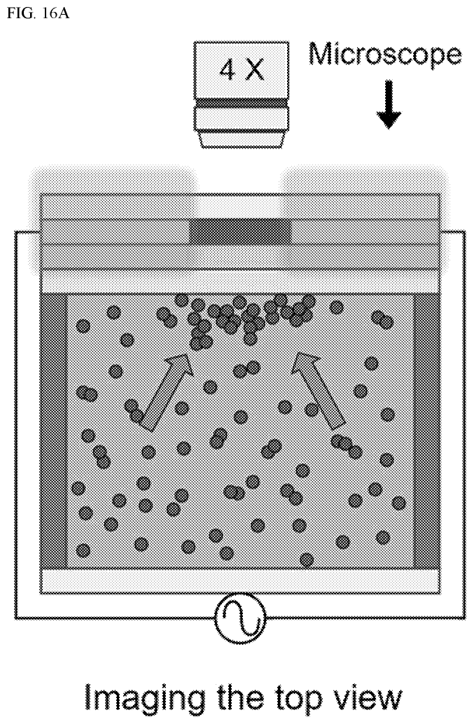

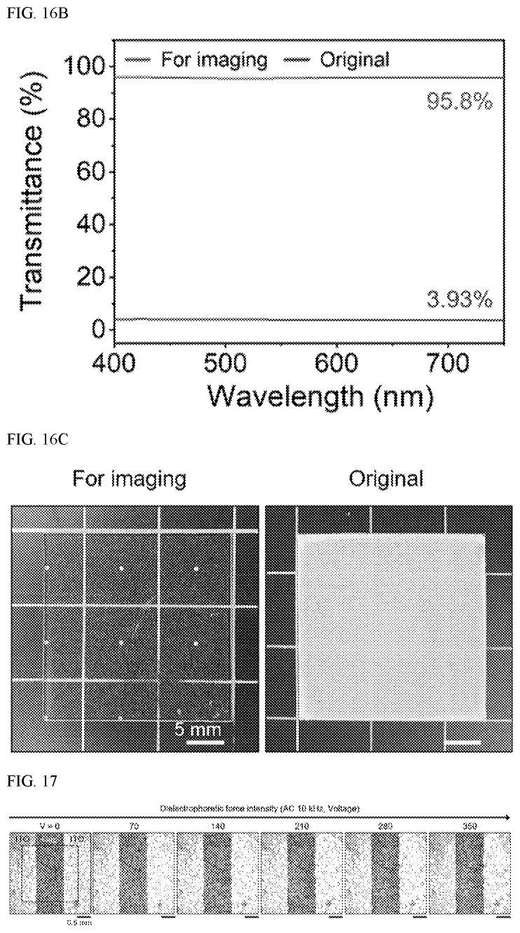

To verify this mechanism, real-time in situ observation of the particle self-assembly process was performed using optical microscopy (OM) (see FIG. 16A). Since the optimized emissive layer is opaque with an average transmittance of 3.93%, an emissive layer with lower phosphor content was used to increase the transmittance to 95.8% (see FIGS. 16B and 16C). The leftmost OM image in FIG. 2C shows the initial state (0 V) in which microspheres are suspended in n-hexadecane. At 70 V, dendritic structures were observed at the edges of the electrodes, which extended to form a conductive bridge at 140 V. Further increasing the voltage increased the percolation network density of the conductive bridges (see FIG. 2D), and dendritic structures beneath the ITO electrodes were also observed above 140 V (see FIG. 2C and FIG. 17). As shown in the series of photographs in FIG. 2E, the magnitude of the DEP force was quantified by the brightness and area of the EL emission of the DUET display at a given frequency (10 kHz). The time-averaged DEP force (F_{DEP}) for a spherical particle in a sinusoidal AC field was calculated by conducting numerical simulations of the electric field distribution:

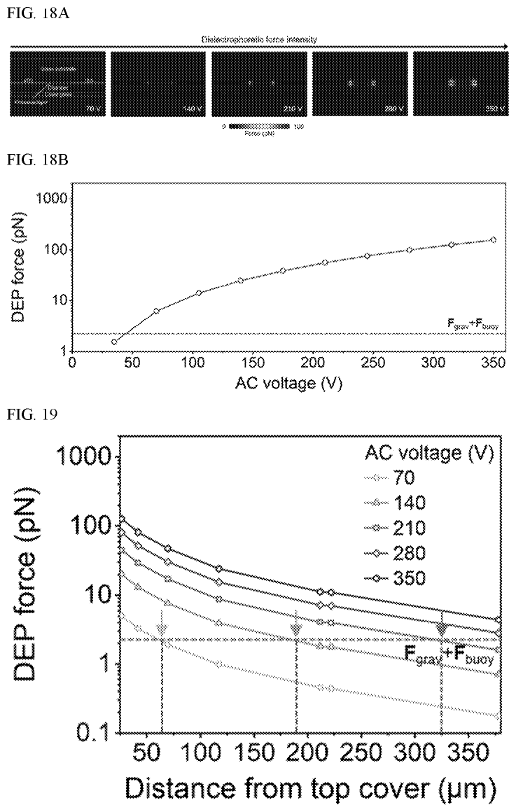

F_{DEP}=2πεₘR³Re[f*_{CM}(ω)]·∇E²^{ᵣₘₛ} (2)

where εₘ is the dielectric constant of the medium, R is the radius of the suspended particle, and ω is the angular frequency of the AC signal (ω=2πf) (see FIG. 18A). At 35 V, 1.54 pN of F_{DEP} was induced beneath the top cover of the chamber (see FIG. 18B), which was below the sum of the gravitational force and buoyant force acting on the microspheres (see Supplementary Notes 2 and 4, and FIG. 19). Since F_{DEP} was not the dominant force acting on the microspheres at this state, the microspheres could not migrate toward the electrode gap to form dendritic structures. Further increasing the voltage to 70 V induced F_{DEP} of 6.18 pN, which surpassed the sum of the gravitational force and buoyant force, enabling dendritic structure formation (see FIG. 2C).

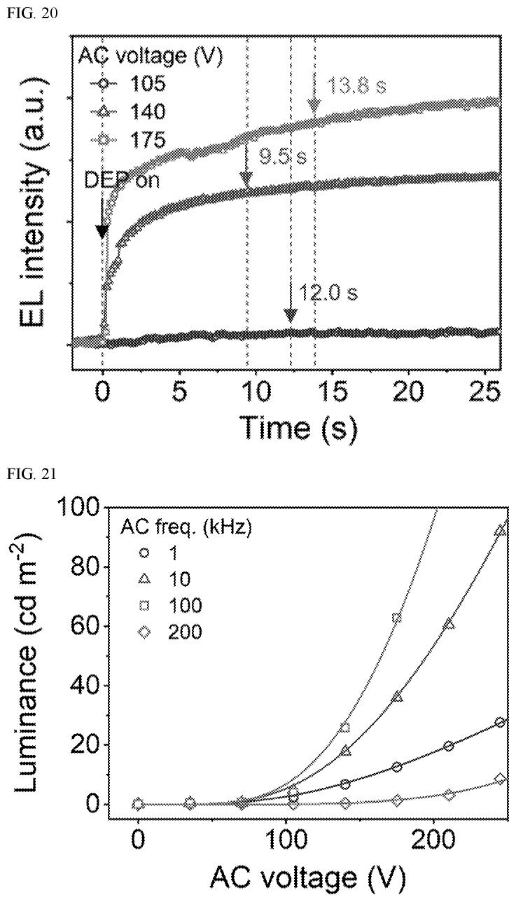

The decrease in electrical impedance change of the DUET display shown in FIG. 2F is consistent with the proposed mechanism that the percolation network density of the microspheres changes in response to the external electric field. Here, the electrical impedance change is defined as ΔZ_{E}/Z_{E0}, where Z_{E0} is the electrical impedance without DEP force and ΔZ_{E} is the difference between Z_{E0} and the electrical impedance at a given DEP force. The corresponding EL change of the display (ΔL/Lₒ) is shown in FIG. 2G, where Lₒ is the lowest detectable luminance and ΔL is the difference between Lₒ and the luminance at a given DEP force. As the DEP force became stronger, the sensitivity of the EL change (S_{X}=Δ[ΔX/Xₒ]/ΔF_{DEP}, where X is either Z_{E} or L) showed a slight increase from 1.32 to 2.86 fN⁻¹. In the EL spectra of the DUET display shown in FIG. 2H, EL intensity increased as a function of AC voltage without spectral shift, with a maximum emission wavelength of 450 nm. When the voltage was changed from 105 V to 175 V, the response time of the DUET display at 10 kHz decreased from 12.0 s to 9.5 s and then increased to 13.8 s (see FIG. 20).

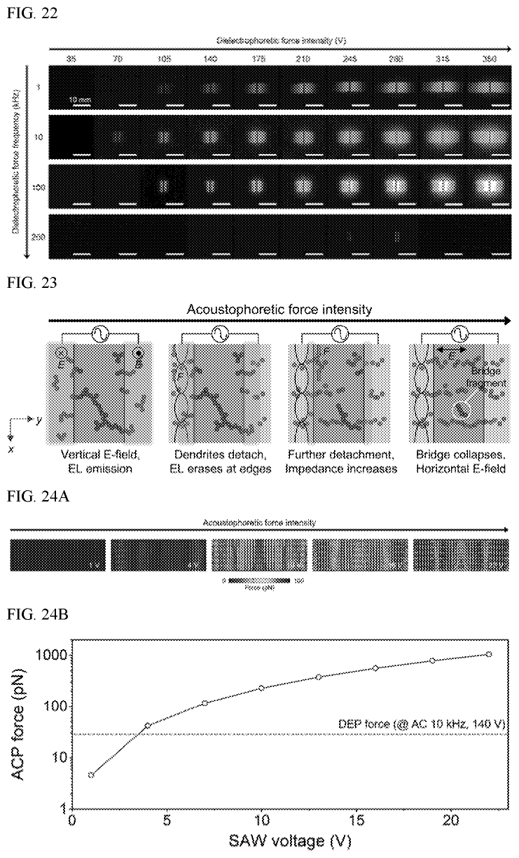

Applying different DEP frequencies ranging from 1 to 100 kHz to the ITO electrodes led to an increase in luminance while the EL light-emitting area of the DUET display decreased (see FIGS. 2I and 2J, respectively; also see FIGS. 21 and 22). However, further increasing the frequency to 200 kHz led to insufficient time for carrier injection, causing the display to show a significant decrease in both luminance and EL area. Therefore, to ensure moderate brightness and EL area during the On-mode while maintaining high sensitivity to ACP forces during the Off-mode, the DUET display was primarily operated at 10 kHz and 140 V, where a luminance of 17.72 cd m⁻² was shown (this will be further discussed below). At 140 V, the response time of the DUET display showed a slight decrease from 11.7 s to 10.0 s as the frequency increased from 1 kHz to 10 kHz, and increased again to 22.6 s when the frequency further increased to 100 kHz (see FIG. 2K).

### [Working Principle and Characteristics of the ACP-Sensing Off-Mode]

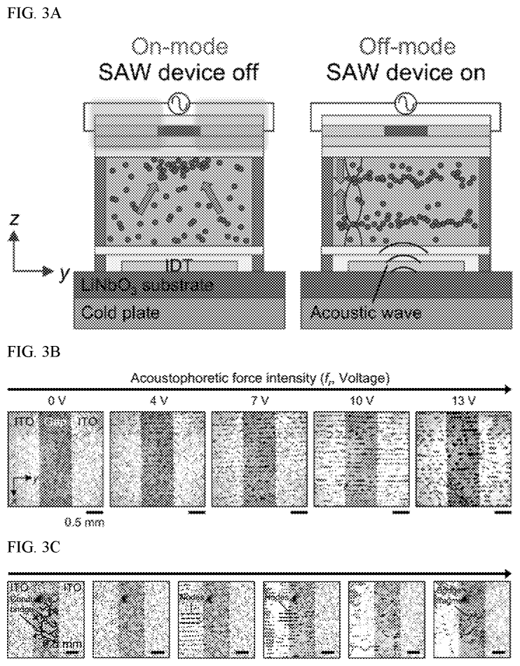

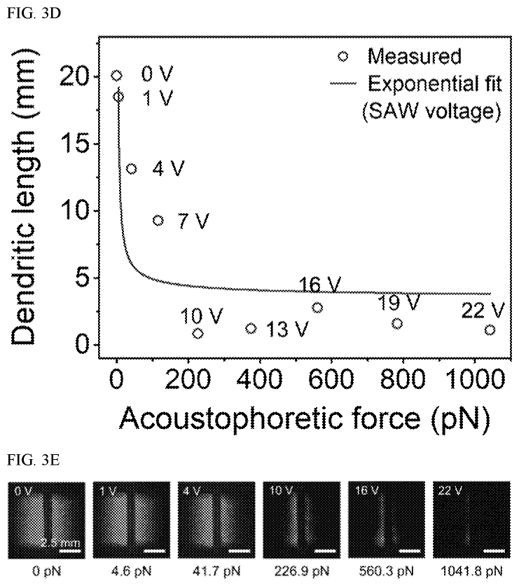

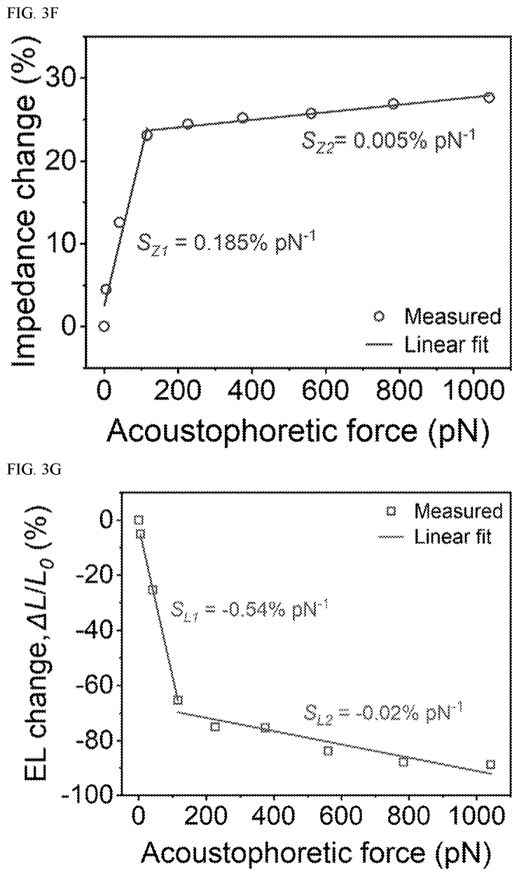

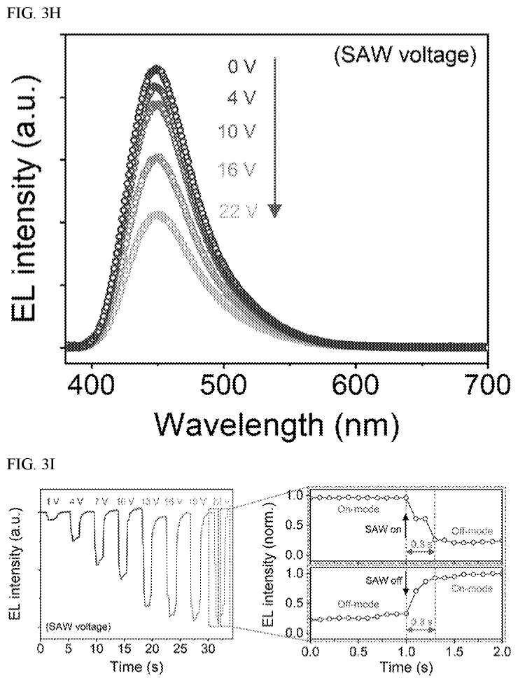

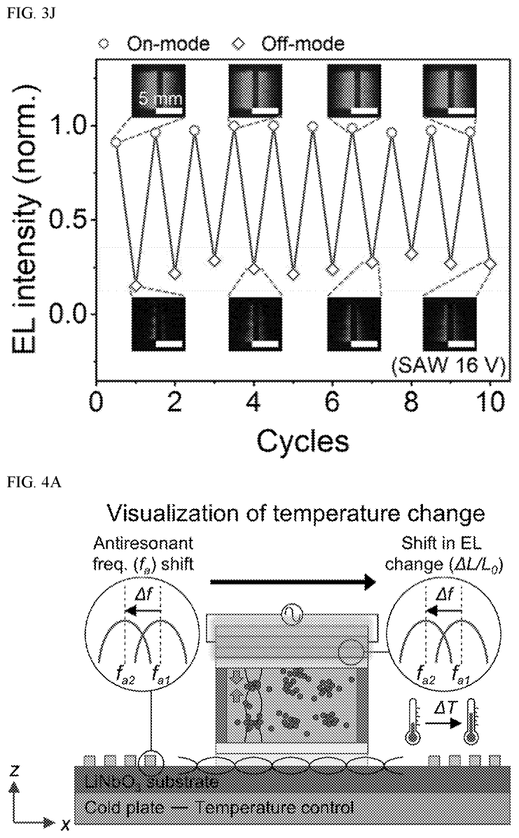

FIG. 3A illustrates the dual-mode operating DUET display mounted on a SAW device. When the resonant frequency (fᵣ, 13.830 MHz) of the SAW device is applied to the IDTs, interference between the two opposing waves gives rise to a standing SAW that leaks into the chamber of the DUET display. In addition, a standing BAW is formed by reflection of waves from the top glass substrate of the DUET display, and together with the SAW, an overall three-dimensional acoustic pressure field is created in the chamber with an interval of approximately 140 μm and 48 μm along the x and z directions, respectively. This standing BAW arises from the significant acoustic impedance (Z_{A}=ρc) mismatch at the glass/n-hexadecane and glass/air interfaces, where p is the density and c is the velocity of the acoustic wave in the material (see Table 2). This causes a large portion of the wave energy to be reflected from the top cover of the chamber, which can be quantified by the reflection coefficient (R):

$$R = \frac{{I}_{r}}{{I}_{0}} = {( \frac{{Z}_{A 2} - {Z}_{A 1}}{{Z}_{A 2} + {Z}_{A 1}} )}^{2} \qquad ( 3 )$$

where Iᵣ and Iₒ are the intensity of the reflected and initial acoustic wave, respectively, and Z_{A1} and Z_{A2} are the acoustic impedance of the first and second material, respectively. The calculated R values for glass/n-hexadecane and glass/air are 0.70 and 0.99, respectively. The path along which the carbon microspheres move toward the nodes or antinodes of the standing wave is determined by the acoustic contrast factor (q):

$$φ = \frac{5 {ρ}_{p} - {ρ}_{m}}{2 {ρ}_{p} + {ρ}_{m}} - \frac{{β}_{p}}{{β}_{m}} \qquad ( 4 )$$

where βₚ is the compressibility of the particle, and ρₚ and ρₘ are the density of the particle and medium, respectively. A positive φ indicates that particles move toward the pressure nodes (lower pressure regions), while a negative φ indicates that particles are directed toward the pressure antinodes (higher pressure regions). Since φ is positive for the system of carbon microspheres suspended in n-hexadecane, the microspheres of the DUET display move toward the pressure nodes.

FIG. 23 illustrates the proposed states of particle self-assembly under different ACP force intensities of the SAW device. Since the ACP force is visualized by how many microspheres are detached from the top cover, the DUET display must first be in the DEP-applied state (On-mode) before receiving the ACP force. Therefore, conductive bridges exist at the electrode gap and EL emission occurs at the initial state when ACP force is not applied (rightmost of FIG. 2A and leftmost of FIG. 3B). When a weak voltage is applied to the IDTs, the dendritic structures beneath the ITO electrodes are disassembled and the corresponding EL emission at the edges is extinguished. Because the electric field is maximized near the electrode gap, microspheres located farther from the electrode gap experience a weaker DEP force and can therefore be more easily detached by the ACP force. As the input voltage of the IDTs increases, detachment of the microspheres near the electrode edges begins to occur and further decrease of the EL emission is observed. When the ACP force becomes several orders of magnitude stronger than the DEP force, the conductive bridges collapse (rightmost of FIG. 3A), the electric field distribution shifts from vertical to in-plane, and EL emission is no longer observed.

The OM images obtained by real-time in situ observation confirmed that the alignment of the microspheres strengthens as the ACP intensity increases (see FIG. 3B). Since the focal plane of the images was at the top cover of the chamber, the microspheres became increasingly out of focus as their movement along the z direction increased with ACP. When the ACP intensity was steadily increased while a constant DEP force (10 kHz, 140 V) was applied (see FIGS. 3C and 3D), the conductive bridges gradually collapsed and the microspheres gathered toward the pressure nodes of the standing wave, consistent with the proposed mechanism shown in FIG. 3B. This resulted in visual quantification of the ACP force through the decrease in EL brightness and area, as shown in the photographs in FIG. 3E. The ACP force (F_{ACP}) for a spherical particle in a standing acoustic wave was calculated by conducting numerical simulations of the acoustic pressure field (see FIG. 24A and Table 2). Generally, the drag forces induced by primary acoustic radiation forces act as the driving mechanism of ACP, which can be determined by the following equation:

$${F}_{ACP} = - ( \frac{π {p}_{0}^{2} {V}_{p} {β}_{m}}{2 λ} ) φsin ( 2 κ x ) \qquad ( 5 )$$

where pₒ is the acoustic pressure, Vₚ is the particle volume, βₘ is the compressibility of the medium, λ is the acoustic wavelength, and k is the acoustic wavenumber (=2π/λ). When 4 V was applied to the SAW device, F_{ACP} surpassed the DEP force of 24.7 pN and became the dominant force (see FIG. 24B). Further increasing the SAW voltage to 22 V induced F_{ACP} of 1041.8 pN, which is 42.2 times greater than the DEP force, enabling the microspheres to remain stably trapped at the pressure nodes without being pulled toward the top cover of the chamber.

As shown in FIG. 3F, the electrical impedance change of the DUET display increased as the applied ACP force increased, as expected. When the ACP force exceeded 115.8 pN, the sensitivity of the electrical impedance change decreased from 0.185% to 0.005% pN⁻¹, which is consistent with the result that the decrease in dendritic length occurs predominantly in the low ACP force regime below 115.8 pN (see FIG. 3D). The EL change also decreased as the ACP force became stronger, and its sensitivity decreased from −0.54% to −0.02% pN⁻¹ when the ACP force exceeded 115.8 pN (see FIG. 3G). Of note, the mechano-optical conversion parameter of the DUET display (defined as the luminance change of the display divided by the acoustic pressure) is approximately 13 orders of magnitude higher than previously reported acousto-responsive displays. Since the DUET display is responsive to piconewton-scale forces, it is compatible with various microsystems in which minute forces are generated. In the EL spectra of the DUET display shown in FIG. 3H, the EL intensity decreased while the maximum emission wavelength of 450 nm was maintained, and no spectral shift occurred, similar to the behavior observed in the On-mode (see FIG. 2H).

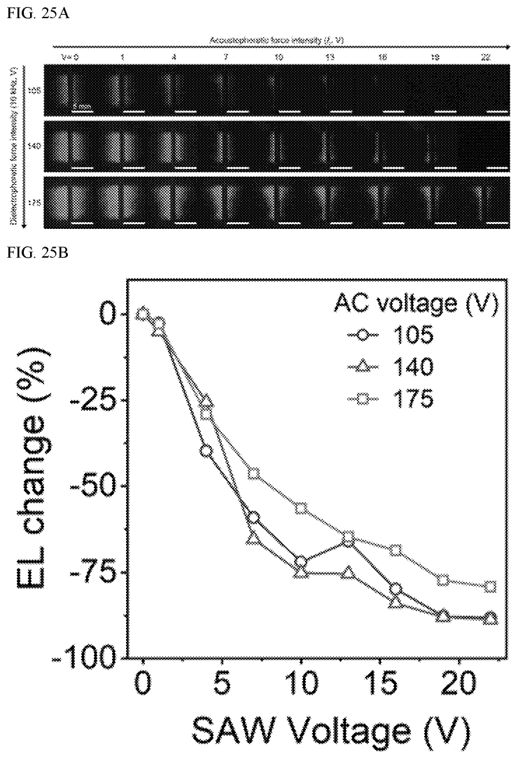

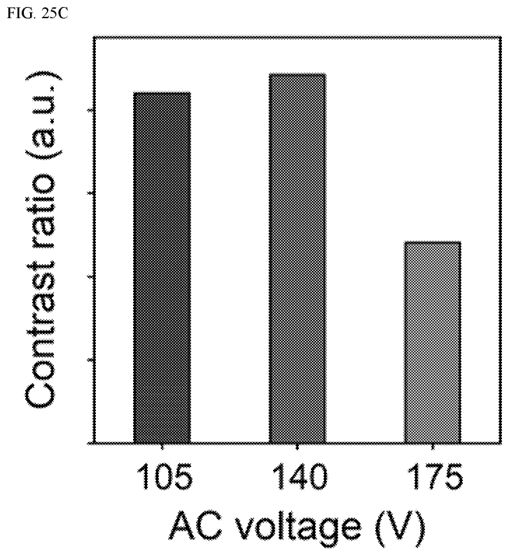

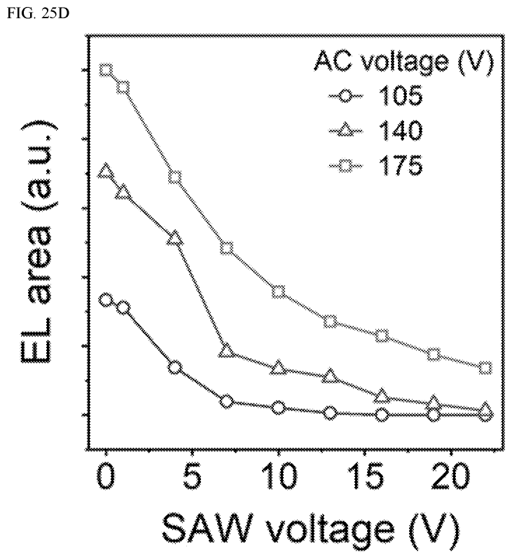

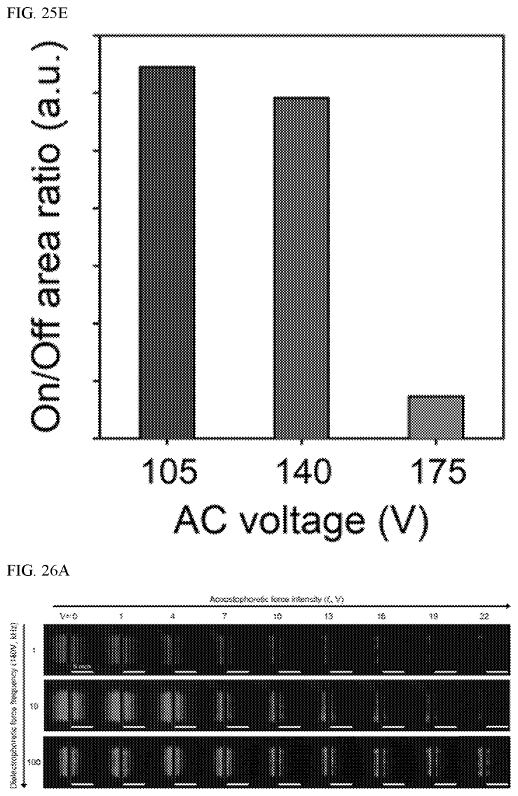

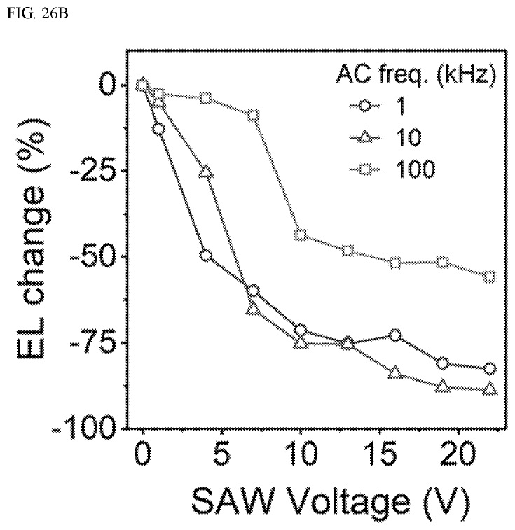

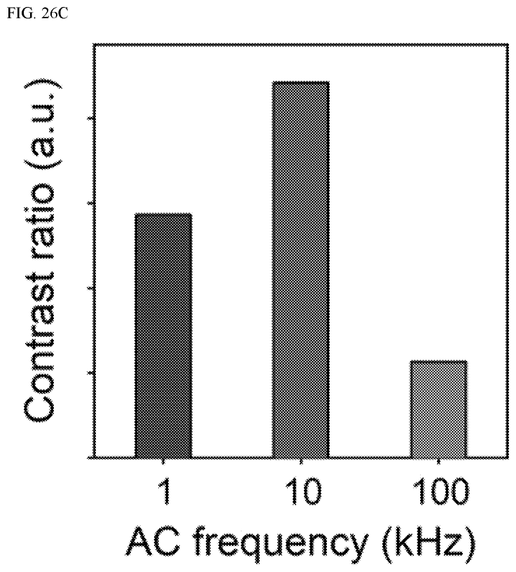

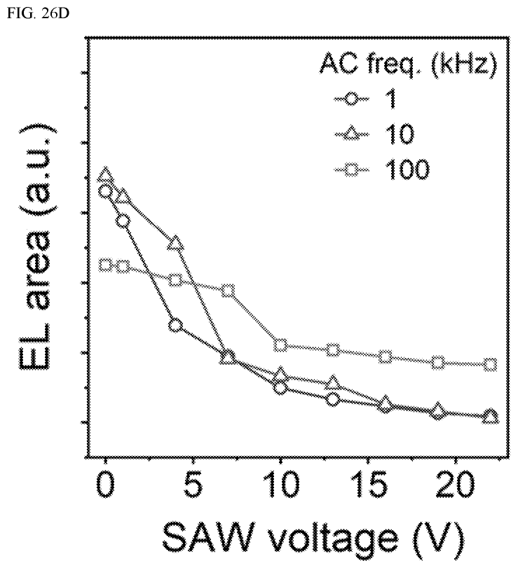

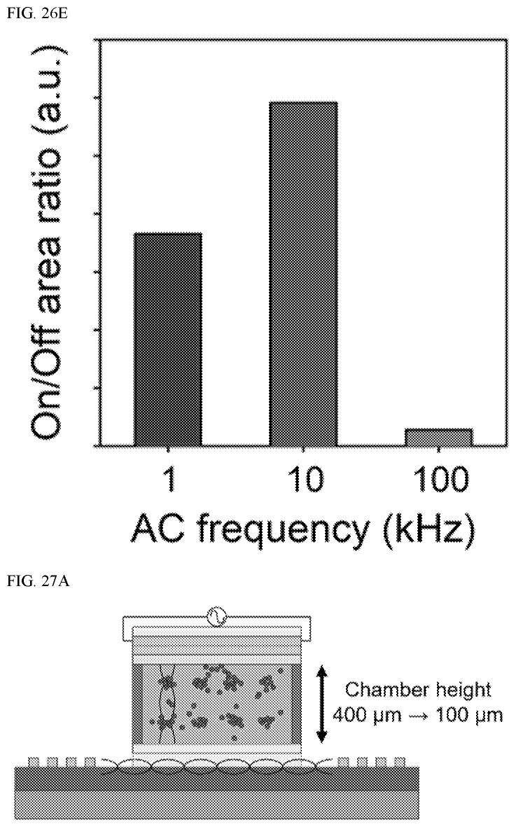

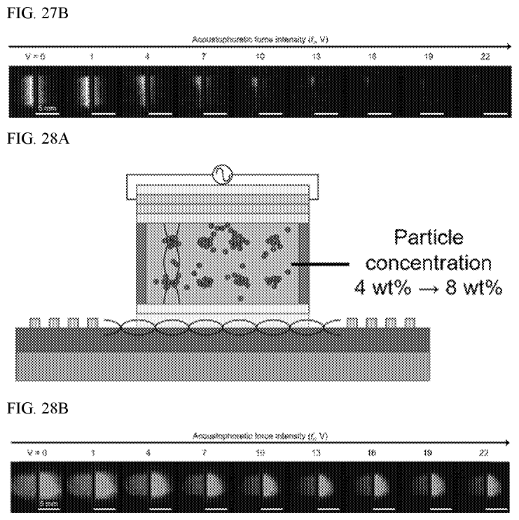

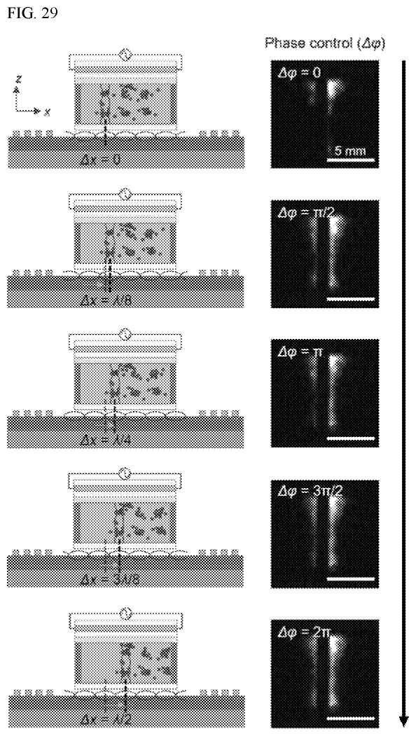

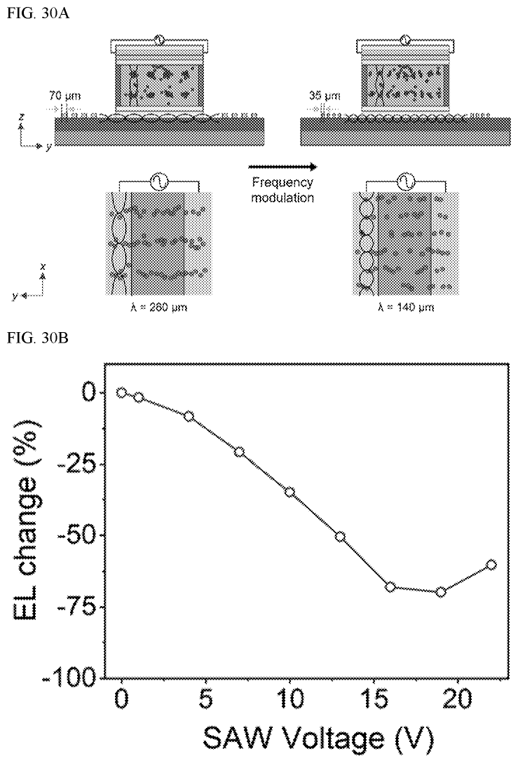

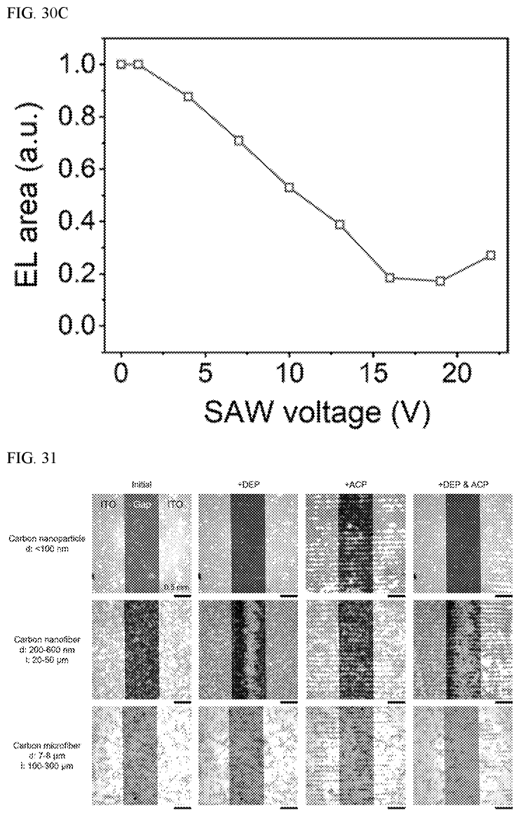

The interplay between the DEP and ACP forces of the DUET display was further explored by examining how the response to the ACP force changed under different DEP intensities and frequencies (see Supplementary Note 5, FIGS. 25 and 26). The DUET display showed the highest contrast ratio (defined as the intensity ratio of the brightest On-mode to the darkest Off-mode) and a high On/Off area ratio (defined as the light-emitting area ratio of the largest On-mode to the smallest Off-mode) when a DEP force of 10 kHz and 140 V was applied. Changing either the intensity or frequency of the DEP force led to a decrease in either the contrast ratio or the On/Off area ratio of the DUET display. Similarly, changing the chamber height or conductive fluid concentration of the DUET display either reduced the sensitivity to the ACP force or resulted in a lower contrast ratio (see Supplementary Note 5, FIGS. 27 and 28). The response of the DUET display was also examined when acoustic wave phase control or frequency modulation was applied. Since phase control causes a shift in the position of pressure nodes within the xy plane, it had minimal effect on the EL emission of the DUET display, further confirming that ACP force sensing of the display is governed by particle movement along the z direction (see FIG. 29). The DUET display was also responsive to a higher ultrasound frequency generated from a different SAW device (fᵣ, 27.54 MHz) (see FIG. 30). The conductive fluid system was also compatible with various carbon-based micro- and nanoparticles, which were responsive to both DEP and ACP forces (see FIG. 31).

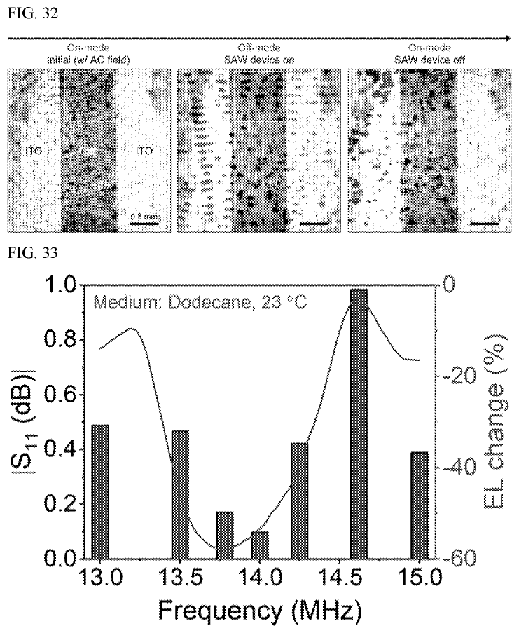

The DUET display is rewritable, as the conductive bridges disrupted by the ACP force can be reconstructed by the DEP force (shifting back to On-mode), and consecutive switching between the two modes is possible. To evaluate its rewritability, OM images were taken during consecutive switching between the two modes (see FIG. 32). After the collapse of the dendritic structures when an acoustic wave was transmitted from the SAW device (Off-mode), new dendritic structures were formed when only the DEP force acted on the microspheres (On-mode). As shown in FIG. 3I, the EL intensity change of the DUET display during consecutive application of various acoustic wave intensities clearly demonstrates its rewritability (left). The response time and recovery time were both 0.3 s when 22 V was applied to the SAW device (right). FIG. 3J shows the stability of the dual mode during ten On-Off cycles, which were performed without significant variation in the EL intensity of each mode.

### [Temperature Change Visualization of DUET Display Via SAW Device Frequency Control]

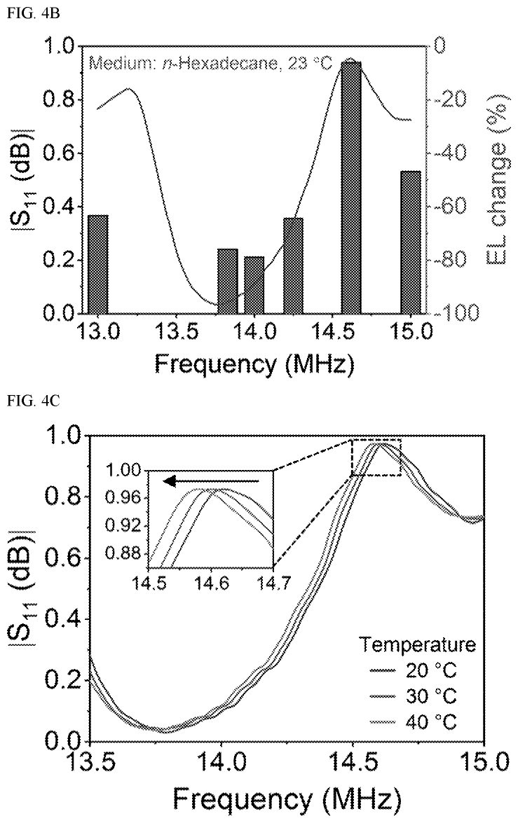

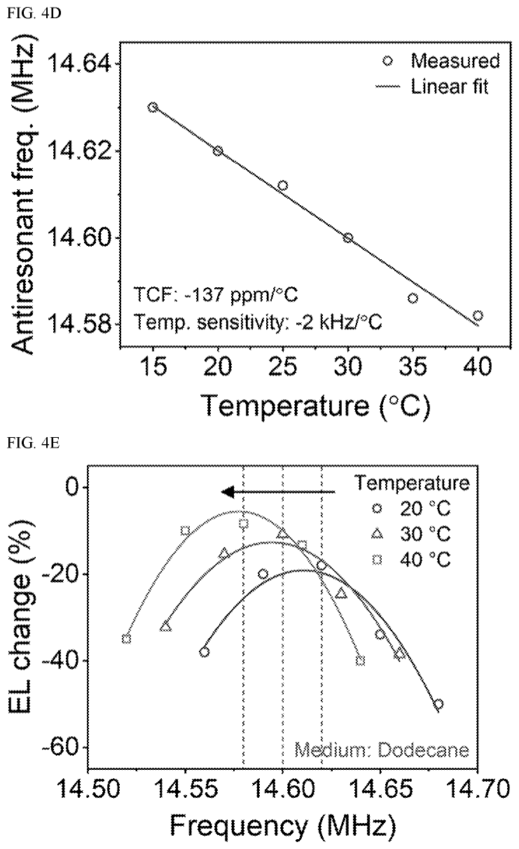

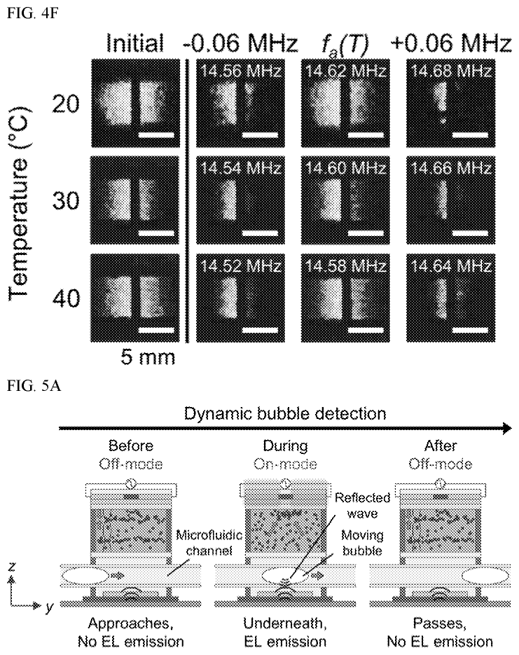

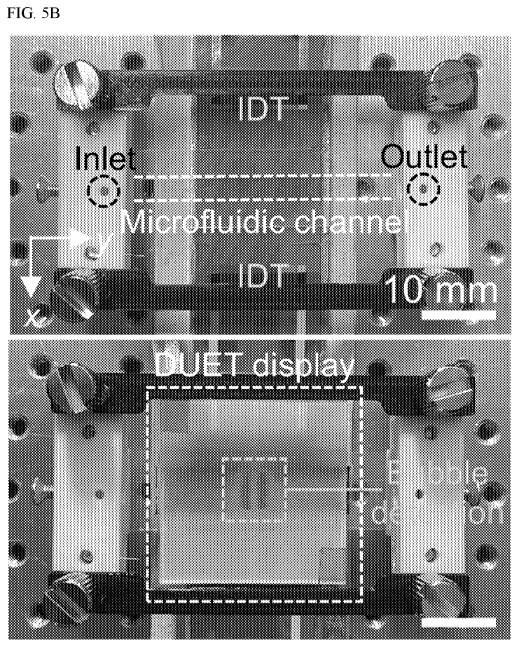

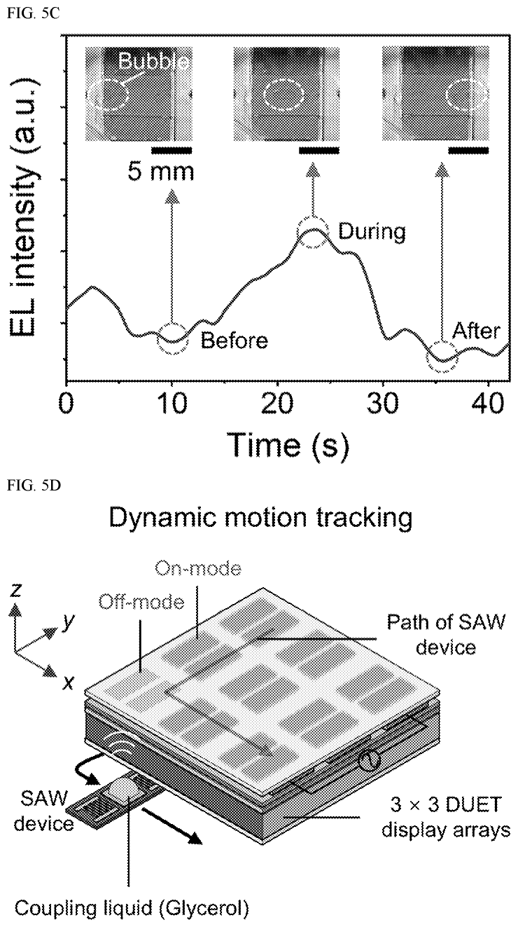

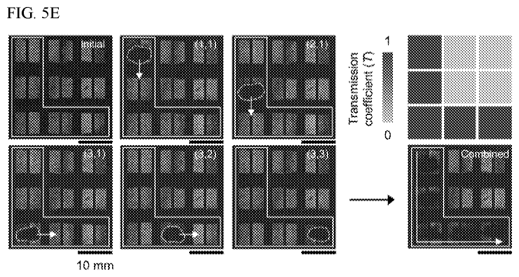

The DUET display not only exhibits an ACP force intensity-dependent EL response under different input voltages of the SAW device (see FIG. 3), but also shows a frequency-dependent EL response at different input frequencies of the SAW device (FIG. 4). When acoustic waves of frequencies near the resonant frequency (fᵣ) of the SAW device are transmitted to the DUET display, the microspheres in the chamber tend to be strongly trapped at the pressure nodes, inducing a strong EL change due to the strong electromechanical coupling of the lithium niobate substrate of the SAW device. However, weak electromechanical coupling near the antiresonant frequency (fₐ) leads to a weak EL change of the DUET display. In addition, SAW devices exhibit a frequency shift when the temperature changes due to the softening of the lithium niobate resonator material, a characteristic that enables temperature-sensing applications of these devices. Therefore, combining the characteristics of the DUET display and the SAW device enables visualization of temperature change, as shown in FIG. 4A. The temperature of the system was controlled by a thermoelectric liquid chiller connected to a cold plate placed beneath the lithium niobate substrate (see FIG. 4A).

First, the absolute value of the scattering parameter (|S₁₁|) of the SAW device was measured from 13 to 15 MHz at room temperature (23 °C) (see FIG. 4B). |S₁₁| indicates the return loss of an RF system, which is closely related to the electromechanical coupling characteristics of lithium niobate in the case of SAW devices. Therefore, the frequencies at which |S₁₁| shows a minimum and maximum value correspond to fᵣ (13.830 MHz) and fₐ (14.615 MHz) of the SAW device of the present invention, respectively. The EL change of the DUET display under different SAW frequencies showed a similar trend to |S₁₁| of the SAW device, with a maximum change of −78.8% near fᵣ and a minimum change of −6.1% near fₐ (see FIG. 4B). FIG. 4C shows the frequency dependence of |S₁₁| of the SAW device at different temperatures. As the temperature increased from 20 °C to 40 °C, the |S₁₁| curve shifted to the left, resulting in a decrease of fₐ from 14.620 MHz to 14.582 MHz. The correlation between the temperature change and fₐ shift was further investigated in FIG. 4D, which showed a temperature sensitivity of −2 kHz/°C from the slope of the linear fit. The effect of temperature on the frequency shift can also be described by the temperature coefficient of frequency (TCF), which is defined as the relative change in frequency with temperature:

$$TCF = \frac{1}{{f}_{r}} \frac{{df}_{r}}{dT} = \frac{1}{v} \frac{dv}{dT} - \frac{1}{λ} \frac{d λ}{dT} \qquad ( 6 )$$

where v and λ are the wave speed and wavelength of the SAW in the resonator material, respectively, and T is the temperature of the SAW device. For the SAW device of the present invention, the calculated TCF in the 15 to 40 °C regime was −137 ppm/°C.

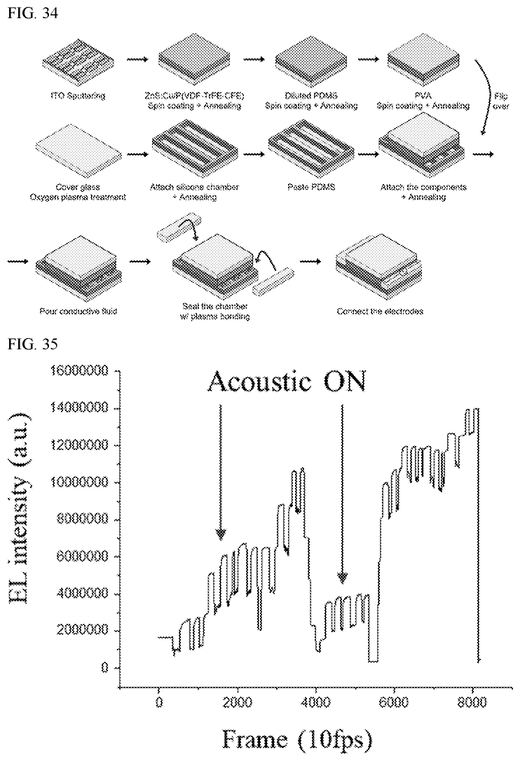

Because the frequency dependence of the EL change of the DUET display was confirmed in FIG. 4B to show a similar trend to |S₁₁| of the SAW device at room temperature, the present inventors further measured how the EL change of the DUET display responds to the frequency shift of the SAW device at temperatures above or below room temperature (see FIG. 4E). Since the EL change of the DUET display is more sensitive near fₐ than near fᵣ, the frequency range was limited to 14.52 to 14.68 MHz. Here, dodecane was used instead of n-hexadecane as the medium for the conductive fluid to ensure stable operation of the DUET display at 20 °C, which is near the freezing point of n-hexadecane (18 °C). The frequency-dependent response of the DUET display using dodecane was confirmed to show a similar response to when n-hexadecane was used (see FIGS. 4B and 33). As the temperature increased, the EL change curve showed an overall shift to the left (FIG. 4E), reflecting the frequency shift of the SAW device with temperature (see FIG. 4C). At each temperature, the frequency at which the DUET display showed minimum EL change matched the fₐ of the SAW device. Therefore, at a given temperature, fₐ of the SAW device can be visually identified by the frequency at which the EL change of the DUET display shows a minimum (see FIG. 4F). In addition, by quantifying the shift of fₐ from 14.615 MHz (fₐ at room temperature), the temperature of the system can be easily determined without the use of complex equipment. Since the DUET display is directly compatible with existing SAW sensors, it also holds potential for visualizing other stimuli such as strain, ultraviolet radiation, and ion concentration.

### [Dynamic Motion Tracking and Non-Invasive Monitoring of Microfluidic Channels]

To further bring the advantages of this versatile display closer to practical reality, the DUET display was demonstrated for non-invasive monitoring of microfluidic channels. As schematically shown in FIG. 5A, a 100-μm-thick silicone microfluidic channel (width, 3 mm) was positioned between the DUET display and the SAW device. Water flows through the microfluidic channel (flow rate, 5.39 μL/min), and the presence of air bubbles inside the channel was monitored by the EL change of the display. The movement of the air bubbles was regulated using a syringe pump connected to the inlet and outlet of the microfluidic channels (see FIG. 5B). Because of the large acoustic impedance difference between water and air, the reflection coefficient R at the water/air interface is 0.99 (see Equation 3 and Table 2), and as a result, the acoustic wave generated from the SAW device is barely transmitted to the DUET display and is instead blocked by the air bubble (the ‘During’ state). Here, the transmitted acoustic energy can be quantified by the transmission coefficient T=1−R. In this case, DEP becomes the dominant force acting on the carbon microspheres inside the chamber of the DUET display, and EL emission occurs (On-mode, see FIG. 5C and center of FIG. 5A). On the other hand, in the absence of the air bubble (the ‘Before’ or ‘After’ state), the water inside the microfluidic channel enables a high T, causing the DUET display to maintain Off-mode by the ACP force generated by the SAW device (see FIG. 5C and left and right of FIG. 5A). Therefore, the DUET display can non-invasively detect and visualize air bubbles inside microfluidic channels, which is useful as a fail-safe architecture in biomedical technologies and industries where early detection of such defects is crucial.

In addition to non-invasive monitoring, this multifunctional display offers dynamic motion tracking of acoustic wave sources (SAW device) based on its dual-mode characteristics. As schematically shown in FIG. 5D, a 3×3 array of DUET displays (pixel size, 7 mm×7 mm) was fabricated, and a SAW device was moved from one pixel to another underneath the display array using an xyz motorized stage (see FIG. 34). First, without the presence of the SAW device, all pixels of the DUET display array showed On-mode at the initial state (FIG. 5E). Introducing the SAW device beneath pixel (1,1) caused that pixel to shift from On-mode to Off-mode due to the transmitted acoustic wave, while all other pixels remained in On-mode. Upon movement of the SAW device from pixel (1,1) to pixel (2,1), pixel (2,1) shifted to Off-mode while pixel (1,1) switched back to On-mode. Because crosstalk between adjacent pixels was negligible, individual pixels could be controlled by the SAW device and the location of the SAW device was detectable by the pixel showing Off-mode. Therefore, as the SAW device moved beneath pixels (1,1), (2,1), (3,1), (3,2), and (3,3), the pixels sequentially shifted from On-mode to Off-mode and back to On-mode. The dynamic motion of the SAW device was monitored from the DUET display array, and by recording a series of images, the path of the SAW device was visually detected to form the letter ‘L’ (see FIG. 5E).

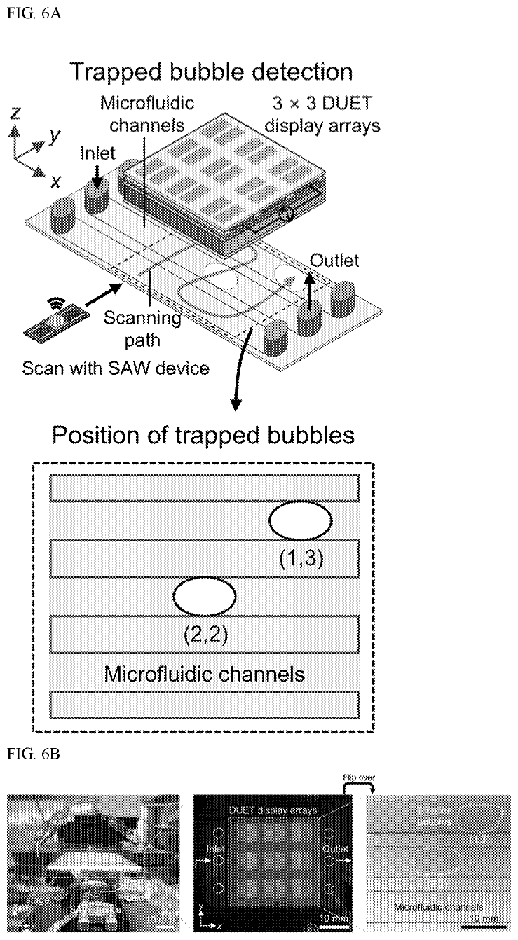

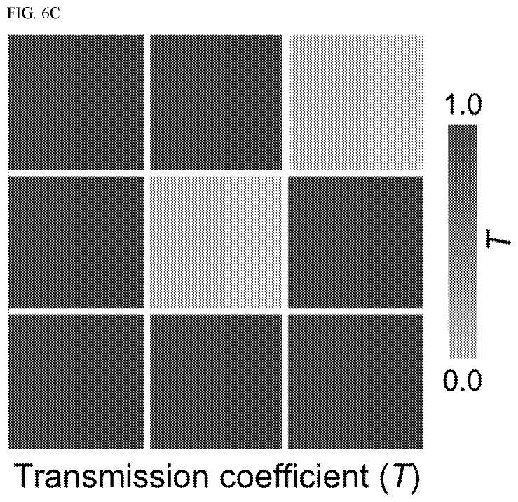

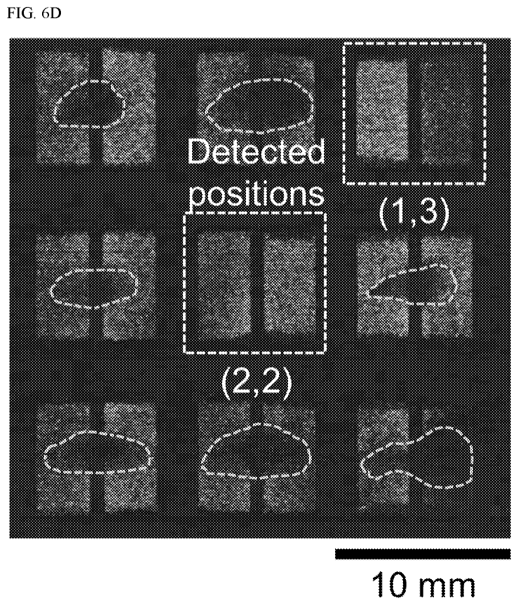

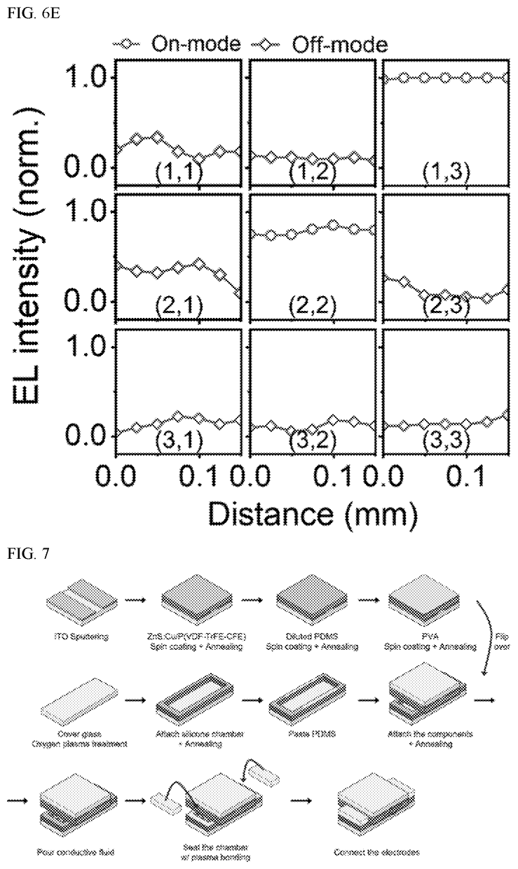

The application of the DUET display array could be further expanded to detection of trapped air bubbles inside microfluidic channels (FIG. 6A, top). A three-lane silicone microfluidic channel of 100 μm thickness (width, 7 mm) was inserted between the DUET display and the SAW device, similar to the dynamic bubble detection design of FIG. 5A. However, unlike FIG. 5A, the air bubbles were at fixed positions beneath pixels (1,3) and (2,2) (see FIG. 6A, bottom). The SAW device moved beneath the microfluidic channels using an xyz motorized stage, identical to the dynamic motion tracking method described in FIG. 5D (see FIG. 6B and Methods). As shown in FIG. 6C, the transmission coefficient T values were almost zero at the microfluidic channels beneath pixels (1,3) and (2,2) due to the air bubbles, whereas all other channels showed T values close to unity. As the SAW device scanned the microfluidic channels, all pixels except for pixels (1,3) and (2,2) shifted from On-mode to Off-mode when the SAW device was positioned beneath them (see FIG. 6D). On the other hand, pixels (1,3) and (2,2) maintained On-mode even when the SAW device was positioned beneath them, indicating the locations of the air bubbles. Therefore, while dynamic motion tracking was possible from the DUET display array through information from the pixels showing Off-mode, the locations of the trapped air bubbles were indicated by the pixels maintaining On-mode (see FIG. 6E). In contrast to conventional ultrasound imaging devices, the DUET display array does not require bulky equipment or complex signal processing, offering a simple, compact, and low-cost system with potential for a wide range of biomedical engineering applications.

### DISCUSSION

The present invention presents a dielectrophoretic-acoustophoretic dual-sensing electroluminescent display that enables direct visualization of forces through precise particle self-assembly. By regulating DEP and ACP forces within a single platform comprising coplanar electrodes, an emissive layer, and a suspension of conductive microparticles, dynamic and responsive visualization capabilities have been achieved. The induced DEP force facilitates the migration of microparticles to form conductive bridges that activate electroluminescence, whose intensity directly reflects the magnitude of the applied force. The introduction of ACP force disrupts these bridges, offering a unique way to modulate the display based on acoustic parameters. This dual-sensing approach not only provides a novel method for visualizing complex physical forces, but also extends its applicability to tasks ranging from temperature change visualization to dynamic motion tracking and non-invasive monitoring of microfluidic systems. The integration of these technologies can pave the way for future advancements in sensing, providing a robust and versatile tool for the direct observation and manipulation of physical forces at the microscopic scale. Furthermore, the display can extend the capabilities of applications in acoustics and may play a pivotal role in the fields of sensing technology, medical imaging, non-destructive testing, and acoustic holography.

### [Methods]

[Materials] Blue fluorescent phosphor microparticles (ZnS:Cu, LP-6864, M-17964-1) were purchased from Lonco Co. LTD, Hong Kong. n-Hexadecane (≥99.0%) was purchased from Alfa Aesar. Poly(vinylidene fluoride-co-trifluoroethylene-co-chlorofluoroethylene) [P(VDF-TrFE-CFE)] was purchased from PIEZOTECH Inc., France. Polydimethylsiloxane (PDMS) and curing agent (Sylgard 184) were purchased from Dowhitech Co. LTD. Silicone films (ELASTOSIL Film 2030 250) were purchased from Silex LTD, United Kingdom. Deionized water (H₂O, 38796), dodecane (anhydrous, ≥99.0%), glycerol (G5516, ≥99.0%), poly(vinyl alcohol) (PVA, M_{w}=130,000 g mol⁻¹), 2-butanone (MEK, ≥99.0%), carbon black microspheres (diameter, 2 to 12 μm), and carbon nanoparticles (<100 nm) were purchased from Sigma-Aldrich. Carbon nanofibers (>95%, diameter: 200 to 600 nm, length: 20 to 50 μm) were purchased from US Research Nanomaterials, Inc., Houston, USA. Carbon microfibers (Grade: XN-100-15M, diameter: 8 μm, length: 150 μm) were purchased from Nippon Graphite Fiber Corporation, Japan. All other organic solvents, including acetone (≥99.5%), 2-propanol (IPA, ≥94.0%), and n-hexane (≥95.0%), were purchased from Duksan reagents and were used as received.

[Preparation of DUET Display] Two coplanar indium tin oxide (ITO) electrodes with a 1 mm gap were formed on a 25 mm×25 mm glass substrate by sputtering (see FIG. 7). The thickness and sheet resistance of the ITO electrodes were 100 nm and 30 22 cm⁻², respectively. The ITO-patterned substrate was sequentially cleaned with acetone and IPA in an ultrasonic bath for 10 min each and then dried in an oven at 65 °C. For the emissive layer, a 10 wt % P(VDF-TrFE-CFE) solution in MEK was prepared by adding ZnS:Cu and P(VDF-TrFE-CFE) powder with a weight ratio of 12.7:1. The mixture was spin coated on the ITO-patterned substrate at 500 rpm for 60 s, which was then annealed at 80 °C for 8 h, forming a ZnS:Cu/P(VDF-TrFE-CFE) composite film. A PDMS solution of 33 wt % in n-hexane was prepared by mixing n-hexane, PDMS liquid, and curing agent with a weight ratio of 20:10:1. The PDMS solution was spin coated on the composite film at 500 rpm for 60 s, which was then annealed at 80 °C for 4 h. For the protective layer, a 2.5 wt % PVA solution in deionized water was prepared by stirring at 70 °C for 2 h. After UV-ozone surface treatment of the PDMS-coated emissive layer for 30 min, the PVA solution was spin coated on the emissive layer at 1,000 rpm for 60 s and annealed at 110 °C for 10 min.

The chamber for the conductive fluid was prepared by bonding a 400-μm-thick silicone film onto a 10.5 mm×30 mm cover glass using O₂ plasma surface treatment (CIONE4, Femto Science, Republic of Korea), which was then annealed in an oven at 60 °C for 10 min. The silicone films were prepared using a cutting plotter (CE7000-60, Graphtec, Japan). The chamber was attached to the spin-coated top cover by applying PDMS at the junction of the two components. A conductive fluid of 4.5 wt % was prepared by dispersing carbon black microspheres in n-hexadecane. The fluid was placed in an ultrasonic bath for 10 min to ensure uniform dispersion of the microspheres. The conductive fluid was then poured into the chamber, and the chamber was sealed with O₂ plasma-treated cover glasses. The DUET display was operated using an alternating current (AC) of 10 kHz and 140 V, supplied by a function generator (33622A, Keysight Technologies, USA) connected to an amplifier (TREK 623B).

[Preparation of SAW Device] The surface acoustic wave (SAW) device was fabricated by depositing aluminum on a 500-μm-thick 128° Y-cut lithium niobate (LiNbO₃) wafer and forming two interdigital transducers (IDTs) through conventional photolithography. The thickness of the IDTs was 2 μm, and the width of each IDT finger and the interval between the IDT fingers were both 70 μm, designed to generate SAW of 280 μm wavelength. The SAW device was bonded to a flat aluminum chip using conductive epoxy to minimize the effect of bulk acoustic wave (BAW) inside the lithium niobate wafer. The SAW device was mounted on a cold plate (P-400S, Takagi, Japan), which was connected to a thermoelectric liquid chiller (LK220, Thorlabs, USA) to maintain a constant temperature of 23 °C during the experiment. For the coupling liquid, deionized water was inserted between the SAW device and the DUET display to ensure high transmission of the generated acoustic wave. Two 100-μm-thick silicone films were used as spacers between the SAW device and the DUET display to maintain the gap and serve as a barrier for the coupling liquid. The RF signal applied to the IDTs was generated from a function generator and delivered through an amplifier (LZY-22+, Mini-Circuits, USA).

[Characterization of Scattering Parameter and Temperature-Dependent Properties] The absolute value of the scattering parameter (|S₁₁|) of the SAW device was obtained by conducting an input frequency sweep from 13 to 15 MHz and measuring the corresponding electrical signal from a SAW generator (BSG F20, Belektronig, Germany). Temperature-dependent characteristics of the SAW device and DUET display were measured by varying the set temperature of the thermoelectric liquid chiller from 15 °C to 40 °C.

[Dynamic Bubble Detection] A microfluidic channel was fabricated by attaching a 100-μm-thick silicone film (channel width, 3 mm) onto a 10.5 mm×50 mm coverslip using O₂ plasma surface treatment and heat treatment at 60 °C for 10 min. Silicone films of 200 μm thickness were attached to the edges of the channels for tubing connection, also using plasma-activated bonding. 3D-printed thermoplastic polyurethane (TPU) tube fittings were connected to the inlet and outlet of the microfluidic channels, and M2 Screws were used to clamp the TPU tube fittings, microfluidic channel, and TPU tube support together to prevent leakage. To combine the SAW device, microfluidic channel, and DUET display, two pairs of 100-μm-thick silicone films were used as spacers between the SAW device and microfluidic channel, and between the microfluidic channel and DUET display, respectively, and deionized water was injected into the spacers to serve as a coupling liquid. During the experiment, AC 1 kHz and 70 V were constantly applied to the DUET display. Using a syringe pump, deionized water containing air bubbles was made to flow into the inlet of the microfluidic channel, pass beneath the DUET display, and exit through the outlet.

[Dynamic Motion Tracking] A 3×3 array of DUET displays (pixel size, 7 mm×7 mm) was fabricated using an ITO-patterned 30 mm×30 mm glass substrate and a 400-μm-thick three-lane silicone film attached to a 30 mm×36 mm cover glass. The specific fabrication conditions are identical to the DUET display preparation procedure (see FIG. 34). The array of DUET displays was clamped at the side frames using a 3D-printed polylactic acid (PLA) holder and was immobilized using an aluminum cylinder rod fixed on an optical breadboard. A SAW device with a resonant frequency of 15.9 MHz, attached to an xyz motorized stage, was also fixed on the optical breadboard beneath the DUET display array. To ensure stable retention of the coupling liquid during the experiment and prevent it from sliding away, glycerol was used instead of deionized water, and a 100-μm-thick square silicone film was used as a barrier to prevent the glycerol from flowing away. Prior to the experiment, the motorized stage was moved along the z direction so that glycerol was sandwiched between the SAW device and the DUET display array. During the experiment, the stage moved within the xy plane, and the mounted SAW device interacted with each pixel. The array of DUET displays was operated at AC 1 kHz and 88 V, and an input voltage of 17.5 V was applied to the SAW device.

[Trapped Bubble Detection] A three-lane microfluidic channel was fabricated by attaching a 100-μm-thick parallel three-lane silicone film (channel width, 7 mm) onto a 30 mm×41 mm PET substrate. The edges of the channels were sealed by attaching 400-μm-thick silicone films with inlet/outlet holes on top, using O₂ plasma surface treatment and heat treatment at 60 °C for 10 min. The microfluidic channel was attached to the bottom (cover glass) of the DUET display array using plasma-activated bonding. Deionized water was injected into the microfluidic channels through the inlet/outlet holes, while two air bubbles were created and positioned beneath pixels (1,3) and (2,2). All other experimental conditions were identical to those described above for dynamic motion tracking.

[Characterization of OM and SEM Imaging] Optical microscopy (OM) imaging of the carbon black microspheres and real-time in situ observation of particle self-assembly were performed using a Ni-U system (Nikon, Tokyo, Japan) equipped with a charge-coupled device (CCD) camera (DS-Q1Mc, Nikon). Scanning electron microscopy (SEM) characterizations were performed using a JSM-7610F-Plus system at an accelerating voltage of 15 kV. The cross-sectional morphologies of the top cover of the DUET display were characterized by preparing samples using an ion-beam assisted cross-section polisher.

[Image Analysis] Electroluminescence (EL) photographs of the DUET display were taken using a USB microscope (AM4113TL, Dino-Lite, Taiwan). The captured images were categorized into three states: (1) both the DUET display and SAW device being off (Off/Off state); (2) the DUET display being on while the SAW device is off (On/Off state); and (3) both the DUET display and SAW device being on (On/On state). The background intensity was calculated using the average intensity of the ‘Off/Off state’ images and the dark regions of the ‘On/Off state’ images. The intensity histogram of the ‘On/Off state’ images was visualized using MATLAB and fitted to a bimodal Gaussian distribution using the ‘fitgmdist’ function. The first and second modes of the Gaussian distribution were categorized as background and light-emitting area, respectively. The light-emitting area and average intensity of the EL emissions were calculated using a threshold determined by the bimodal Gaussian fitting.

[Simulation of Electric and Acoustic Pressure Fields] Computational modeling was performed using COMSOL Multiphysics 6.1. The electric field simulations were conducted without modeling the SAW device, and the PDMS coating and PVA protective layer of the DUET display were omitted. The thickness of the ITO electrodes was modeled as 500 nm, while all other dimensions were set equal to the experimental device. The AC/DC module was used for applying alternating current to the ITO electrodes and calculating the electric field distribution in the chamber. For the acoustic pressure field simulations, a coverslip was used as the top cover of the chamber instead of the spin-coated glass substrate. All other dimensions were set equal to the experimental device. The AC/DC module was used for applying electrical AC signals to the IDTs of the SAW device, and the acoustics module was used for modeling the transmission of acoustic waves from the SAW device to the DUET display and estimating the acoustic pressure fields in the chamber. The material parameters not adopted from the material library of the software are listed in Tables 1 and 2.

### [Supplementary Note 1. Performance Optimization of Emissive Layer]

Prior to the investigation of the dielectrophoretic (DEP) and acoustophoretic (ACP) response characteristics of the DUET display, optimization of the emissive layer of the display was performed. First, the effect of the type of dielectric polymer used in the emissive layer composite on the operating voltage of the DUET display was examined (see FIG. 11A). The DUET display using P(VDF-TrFE-CFE) always showed a higher luminance compared to the display using a PDMS matrix. In addition, the turn-on voltage (defined as the voltage at which a luminance of 1 cd m⁻² is achieved) was lower at 70 V for the display using the P(VDF-TrFE-CFE) matrix, whereas it was 175 V for the display using PDMS. AC-EL displays driven by the hot-electron impact excitation mechanism require a strong local electric field (E_{local}) around the luminescent particles, which can be calculated by the following equation:

$${E}_{local} = {E}_{avg} \frac{3 {ε}_{p}}{2 {ε}_{p} + {ε}_{ZnS} - φ ( {ε}_{ZnS} - {ε}_{p} )} \qquad ( S1 )$$

where E_{avg} is the average electric field acting on the emissive layer, φ is the volume ratio of the phosphors in the emissive layer, and εₚ and ε_{ZnS} are the dielectric constant of the polymer matrix and ZnS phosphor, respectively. A higher εₚ permits a stronger E_{local}, enabling higher excitation efficiency at a given input voltage. Since P(VDF-TrFE-CFE) has a higher dielectric constant (55) compared to PDMS (εₚ=2.3), it induces a stronger E_{local}, which can improve the luminescent brightness of the DUET display.

To confirm the role of the PDMS coating on the emissive layer, the EL performance of DUET displays with and without the coating was measured (see FIG. 11B). The DUET display with PDMS coating showed a typical luminance-voltage (L-V) curve, while the display without PDMS coating did not show EL emission due to short-circuiting of the electrodes (see inset of FIG. 11B). In addition, direct exposure of the PDMS-coated emissive layer to n-hexadecane caused swelling, which induced asymmetric emission from the light-emitting units (see inset of FIG. 11C). As a result, the electric field became concentrated in one of the light-emitting units, making the emissive layer susceptible to damage, and the luminance of the DUET display decreased at a given input voltage (see FIG. 11C).

Comparison studies of the EL performance by varying the emissive layer thickness, ZnS:Cu-to-polymer ratio (ZnS/Polymer), and concentration of the composite solution (Polymer/MEK) were also performed (see FIG. 12). The thickness of the emissive layer was controlled by the spin speed (rpm) used for coating the composite solution, and the layer coated at 500 rpm showed the highest luminance of 457 cd m⁻² at 350 V (see FIG. 12A). Increasing the spin speed to 2,000 or 8,000 rpm resulted in a decrease in performance, with both cases showing a luminance of 285 cd m⁻² at 350 V. These results suggest that when the average emissive layer thickness falls below the size of the ZnS:Cu phosphors (diameter, 25±5 μm), it becomes difficult for the phosphors to be embedded in the polymer matrix, which may substantially increase q, reducing E_{local}. It should be noted that fabricating a uniform emissive layer was difficult at spin speeds below 500 rpm.

When ZnS/Polymer=4, the display showed a luminance of 160 cd m⁻² at 350 V, and performance improved as the ratio increased to 13 (see FIG. 12B). This is analogous to the previous case, where an emissive layer thickness below 20 μm could cause an abrupt increase in q. In contrast, further increasing the ZnS/Polymer ratio to 16 caused the emissive layer thickness to exceed the phosphor size, resulting in a weaker average electric field (E_{avg}) and consequently a reduced E_{local}, leading to a decreased luminance of 298 cd m⁻² at 350 V.

Finally, comparing the L-V curves at different Polymer/MEK compositions, the luminance of the DUET display improved from 158 cd m⁻² as the polymer concentration increased from 5 wt % to 10 wt %, while further increasing to 15 wt % led to a decrease in EL performance to 397 cd m⁻² at 350 V (see FIG. 12C).

### [Supplementary Note 2. Parameter Studies of Display Components]

To measure the distance over which the DEP force can act on the carbon black microspheres, the effect of chamber height on the luminance of the DUET display was evaluated (see FIG. 13A). The rate of improvement in EL luminance began to decrease when the chamber height exceeded 300 μm, indicating that the maximum radial distance over which particle manipulation can occur is in the range of 300 to 400 μm. To trap a particle using DEP force (F_{DEP}), it must overcome the one-dimensional thermal force of Brownian motion:

$${F}_{DEP} > \frac{kT}{2 R} \qquad ( S2 )$$

where T is the ambient temperature (23 °C), k is the Boltzmann constant, and R is the radius of the spherical particle (3.5 μm). Here, the classical definition of the trapping radius is defined as the maximum radial distance at which Equation S2 is satisfied. However, the calculated trapping radius of the present system exceeded the optimized chamber height of the DUET display (400 μm). This is because the DEP force induced by the high operating voltage of the DUET display is orders of magnitude larger than the one-dimensional thermal force (5.84 fN). Therefore, a different definition of the trapping radius is applied for the present system, which is further explained in Supplementary Note 4.

Since the ability to reduce the size of the DUET display could further expand its utility, the display performance at different electrode gap sizes was investigated (see FIG. 13B). As the gap size decreased, the overall luminance increased at a given voltage due to the increase in the induced DEP force. The turn-on voltage also showed a slight decrease from 70 V (1-mm gap) to 63 V (0.5-mm gap). Therefore, the DUET display has the flexibility to be fabricated in various sizes, and is suitable for implementation in an array configuration, as demonstrated in FIGS. 5 and 6.

The DUET display showed an overall increase in luminance as the particle concentration of the conductive fluid increased, approaching the upper limit of the display measured using deposited aluminum as a conductive bridge (see FIGS. 13C and 14A). When the aluminum area is identical to the maximum active area of the DUET display (6.5 mm×25 mm), the maximum luminance of 970 cd m⁻² was observed at AC 100 kHz and 350 V (see FIG. 14B). Furthermore, reducing the aluminum area to 6.5 mm×6.5 mm (the active area of the DUET display at 10 kHz and 140 V) induces a higher electric field at a given voltage, and the luminance increased up to 1,606 cd m⁻² at 100 kHz and 350 V (see FIG. 14C).

### [Supplementary Note 3. The Bounds of the Real Part of the Clausius-Mossotti Factor]

The complex dielectric permittivity ε*(ω) can be approximated using the following low-frequency approximation:

$${ε}^{*} ( ω ) = ε - \frac{i σ}{ω} \qquad ( S3 )$$

where i is the imaginary unit, and ε and σ are the dielectric constant and electrical conductivity of the material, respectively. Based on Equation S3, the first limit of the real part of the Clausius-Mossotti factor (Re[f*_{CM}(ω)]) occurs in the low-frequency range through the ionic contribution of conductivity:

$$Re [ {f}_{CM}^{*} ( ω \to 0 ) ] = \frac{{σ}_{p} - {σ}_{m}}{{σ}_{p} + 2 {σ}_{m}} \qquad ( S4 )$$

where σₚ and σₘ are the electrical conductivity of the particle and medium, respectively.

Another limit is considered in the high-frequency range through the ionic contribution of the dielectric constant:

$$Re [ {f}_{CM}^{*} ( ω \to ∞ ) ] = \frac{{ε}_{p} - {ε}_{m}}{{ε}_{p} + 2 {ε}_{m}} \qquad ( S5 )$$

where εₚ and εₘ are the dielectric constant of the particle and medium, respectively.

Using these equations, it was confirmed that the value of Re[f*_{CM}(ω)] is always positive for the DUET display, and that a crossover frequency at which Re[f*_{CM}(ω)]=0 does not exist (see FIG. 2B).

### [Supplementary Note 4. Dielectrophoretic Trapping Radius of DUET Display]

The sum of the gravitational force (F_{grav}) and buoyant force (F_{buoy}) acting on a suspended spherical particle is expressed as:

$${F}_{grav} + {F}_{buoy} = \frac{4}{3} π {R}^{3} ( {ρ}_{p} - {ρ}_{m} ) g \qquad ( S6 )$$

where R is the particle radius, g is the gravitational acceleration, and ρₚ and ρₘ are the density of the particle and medium, respectively. For a system in which carbon microspheres (ρₚ=1.95 g cm⁻³) are suspended in n-hexadecane (ρₘ=0.77 g cm⁻³), the sum of F_{grav} and F_{buoy} was calculated to be 2.08 pN. Because of the large size of the microspheres and the large density difference between the particle and medium, the sum of these forces is comparable to the DEP force in the low operating voltage regime (approximately 50 V) (see FIG. 18B).

Therefore, in the present invention, the trapping radius of the carbon microspheres in the DUET display is defined as the maximum radial distance at which the condition F_{DEP}>F_{grav}+F_{buoy} is satisfied (see FIG. 19). However, the trapping radius at an operating voltage of 140 Vis 199.5 μm, which still falls short of the optimized chamber height of 400 μm (see FIG. 13A). While the definition of the trapping radius considers only the external forces directly acting on a single particle, the actual DUET display system contains a fluid of high particle concentration. Since the polarization of the particles induces electrostatic attraction between neighboring particles, interactions between particles can occur in a chain-reaction-like manner, potentially enabling particle manipulation beyond the trapping radius.

### [Supplementary Note 5. Interplay Between the DEP and ACP Forces of the DUET Display]

A trade-off between the DEP and ACP forces was observed in the DUET display. Increasing the DEP force resulted in a brighter On-mode of the DUET display, but made it more difficult to achieve a completely dark Off-mode by the ACP force alone (see FIG. 25A). On the other hand, applying a weaker DEP force caused the EL intensity of the On-mode to decrease, but made it easier for the ACP force to completely extinguish the EL emission, enabling a darker Off-mode. When 140 V was applied to the ITO electrodes, a balance between the two forces was achieved, where moderate brightness was maintained in the On-mode and a completely dark Off-mode was obtained when 22 V was applied to the SAW device (see FIGS. 25B and 25D). This balance provided a high contrast between the two modes of the DUET display, showing the highest contrast ratio and a high On/Off area ratio (see FIGS. 25C and 25E). Similarly, applying a DEP frequency of 10 kHz resulted in the optimal balance between the DEP and ACP forces, and increasing or decreasing the frequency led to a reduction in both the contrast ratio and the On/Off area ratio (see FIG. 26).

As the present inventors conducted various parameter studies in Supplementary Note 2 on how the components of the DUET display affect the On-mode performance, investigations were similarly performed on how they affect the Off-mode. Since the acoustic pressure field interval along the z direction is 48 μm, a single pressure node along the z direction is formed at a chamber height of 100 μm. A DUET display with a chamber thickness of 100 μm also showed responses to the ACP force (see FIG. 27). However, the low chamber height limited the number of microspheres in the chamber, which led to a low contrast between the two modes (see FIG. 13A). In addition, increasing the particle concentration of the conductive fluid from 4.5 to 8 wt % resulted in a brighter On-mode, but the increased electrostatic attraction between particles made it more difficult to completely extinguish the EL emission (see FIGS. 13C and 28).

TABLE 1
[Parameters used in the simulations of electric field distribution
and calculations of the Clausius-Mossotti factor and DEP forces]

| | | Electrical | |
|---|---|---|---|
| | Dielectric | conductivity | |
| Materials | constant (ε) | (σ, S m⁻¹) | Size* |
| Microsphere | 37.12 (measured) | 70000 | d: 7 μm |
| n-Hexadecane | 2.08 (measured) | 10⁻¹² | |
| Glass (coverslip) | 7.8 | 10⁻¹¹ | |
| ITO | 10¹⁰ (materials | 13000 | t: 500 nm |
| | library) | | |
| P(VDF-TrFE-CFE) | 55 | 10⁻⁵ | t: 38 μm |

*d: Diameter/t: Thickness of the layer

TABLE 2
[Parameters used in the simulations of acoustic pressure
field distribution and calculations of acoustic impedance]

| | Density | Speed of sound | |
|---|---|---|---|
| Materials | (kg m⁻³) | (m s⁻¹) | Properties* |
| Microsphere | 2000 | | d: 7 μm |
| n-Hexadecane | 769.8 | 1339 | μ: 0.00035 Pa s, |
| | | | μB: 0.0002 Pa s |
| Glass (coverslip) | 2210 | 4540 | ν: 0.22, E: 50 GPa |
| PDMS (silicone | 965 | 1020 | |
| chamber) | | | |
| Water (coupling | 1000 | 1490 | |
| liquid) | | | |
| Air | 1.293 | 343 | |
| LiNbO₃ | 4700 | | f: 14 MHz, λ: |
| | | | 280 μm, t: 500 μm |

*d: Diameter/μ: Dynamic viscosity/μ_{B}: Bulk viscosity/ν: Poisson's ratio/E: Young's modulus/f: Frequency of surface acoustic wave/λ: Wavelength of surface acoustic wave/t: Thickness

### [Fabrication Example Using BAW]

In the embodiments described above, the device structure utilizing SAW and experimental examples based on the generation of standing acoustic waves produced thereby were described. However, the present invention is not limited to SAW and can also utilize BAW. In the embodiments described above, two electrodes were formed coplanar on the substrate to generate SAW. However, when two electrodes are formed facing each other with the substrate interposed therebetween, BAW passing through the matrix unit from the bottom of the matrix unit can be generated. Such a structure also falls within the scope of the present invention. When BAW is utilized, a standing acoustic wave can be formed inside the chamber, through which an acoustic radiation force acts on the carbon black microspheres, enabling disruption and reformation of the conductive bridge.

[EL Intensity Change of DUET Display with BAW Transducer Operation]

Referring to FIG. 35, during the initial phase of the experiment (frames 0 to approximately 1500), only the DEP force is applied, and the EL intensity shows a gradual increasing trend. This reflects the process by which carbon black microspheres migrate toward the electrode gap by dielectrophoretic force and conductive bridges are progressively formed. Subsequently, at the moment the BAW transducer is activated (Acoustic ON, indicated by the arrow), a sharp decrease in EL intensity is observed, which is the result of the conductive bridge being disrupted as the microspheres migrate toward the pressure nodes of the standing acoustic wave formed by the bulk acoustic wave. Since the DEP force continues to act even after the BAW is applied, the bridge undergoes repeated reformation and disruption, resulting in an oscillating pattern of EL intensity. After the second Acoustic ON event (approximately frame 4500), the same pattern is repeated, confirming that the transition to Off-mode by BAW is reproducible.

[EL Photographs of DUET Display with BAW Transducer Operation]

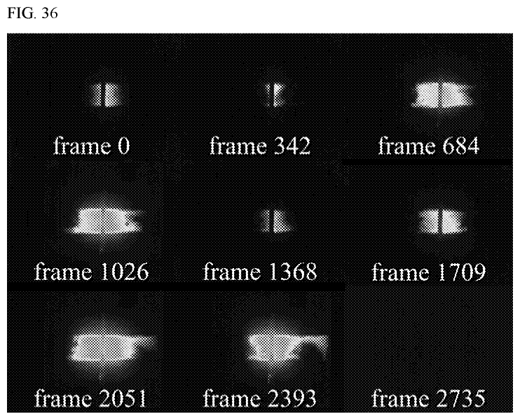

Referring to FIG. 36, at frame 0, the conductive bridge is in its initial formation stage, and a narrow light-emitting region is observed centered around the middle of the electrode gap. As the frames progress to 342 and 684, the light-emitting area gradually expands, reflecting the growth of the bridge by DEP force and the increase in percolation network density. At frame 1026, the typical On-mode state with the widest light-emitting area is confirmed. At frame 1368, the light-emitting area begins to contract with the application of BAW, and at frame 1709, a state in which part of the bridge has been disrupted and light emission has decreased is observed. Subsequently, at frames 2051 and 2393, light emission increases again due to bridge reformation by DEP force, and at frame 2735, recovery of a light-emitting area comparable to the On-mode is confirmed.

Although the present invention has been described with reference to preferred embodiments thereof, those skilled in the art will appreciate that various modifications and changes can be made to the present invention without departing from the spirit and scope of the invention as set forth in the claims below.

What is claimed is:

1. A dual-sensing alternating current electroluminescent device comprising:
an acoustic wave generating unit comprising: a substrate; a first electrode formed adjacent to the substrate; and a second electrode formed adjacent to the substrate and spaced apart from the first electrode;
a matrix unit positioned on the acoustic wave generating unit and comprising: a chamber capable of receiving a fluid therein; a fluid received within the chamber; and conductive particles dispersed in the fluid;
an electroluminescent layer positioned on the matrix unit and configured to emit light when a voltage is applied thereto;
a third electrode positioned on the electroluminescent layer and formed coplanar with the electroluminescent layer; and
a fourth electrode positioned on the electroluminescent layer, formed coplanar with the electroluminescent layer, and spaced apart from the third electrode,
wherein the device further comprises an acoustic wave power supply configured to apply a voltage to the first electrode and the second electrode to form a standing acoustic wave in the matrix unit, and
wherein the device further comprises an alternating current power supply configured to apply an alternating current voltage to the third electrode and the fourth electrode.

2. The dual-sensing alternating current electroluminescent device of claim 1, wherein the first electrode and the second electrode are formed facing each other with the substrate interposed therebetween, and the acoustic wave formed by the acoustic wave power supply is a bulk acoustic wave.

3. The dual-sensing alternating current electroluminescent device of claim 1, wherein the first electrode and the second electrode are formed coplanar and spaced apart from each other on the substrate, and the acoustic wave formed by the acoustic wave power supply is a surface acoustic wave.

4. The dual-sensing alternating current electroluminescent device of claim 1, wherein the first electrode and the second electrode are formed in an interdigitated configuration.

5. The dual-sensing alternating current electroluminescent device of claim 1, wherein the conductive particles comprise carbon black microspheres.

6. The dual-sensing alternating current electroluminescent device of claim 1, wherein the fluid is a non-polar fluid.

7. The dual-sensing alternating current electroluminescent device of claim 1, wherein the electroluminescent layer comprises ZnS:Cu.

8. The dual-sensing alternating current electroluminescent device of claim 1, wherein when an alternating current voltage is applied to the third electrode and the fourth electrode and no standing acoustic wave is applied to the matrix unit through the first electrode and the second electrode, the conductive particles in the fluid migrate by dielectrophoresis to form a conductive bridge connecting the third electrode and the fourth electrode in an upper portion of the fluid, thereby inducing light emission from the electroluminescent layer.

9. The dual-sensing alternating current electroluminescent device of claim 8, wherein when a standing acoustic wave is applied through the first electrode and the second electrode while the conductive bridge is formed, the conductive particles migrate toward nodes of the standing acoustic wave and the conductive bridge is disrupted, resulting in extinction of light emission from the electroluminescent layer.

10. A temperature sensing device comprising a dual-sensing alternating current electroluminescent device, the dual-sensing alternating current electroluminescent device comprising:
an acoustic wave generating unit comprising: a substrate; a first electrode formed adjacent to the substrate; and a second electrode formed adjacent to the substrate and spaced apart from the first electrode;
a matrix unit positioned on the acoustic wave generating unit and comprising: a chamber capable of receiving a fluid therein; a fluid received within the chamber; and conductive particles dispersed in the fluid;
an electroluminescent layer positioned on the matrix unit and configured to emit light when a voltage is applied thereto;
a third electrode positioned on the electroluminescent layer and formed coplanar with the electroluminescent layer;
a fourth electrode positioned on the electroluminescent layer, formed coplanar with the electroluminescent layer, and spaced apart from the third electrode;
an acoustic wave power supply configured to apply a voltage to the first electrode and the second electrode to form a standing acoustic wave in the matrix unit; and
an alternating current power supply configured to apply an alternating current voltage to the third electrode and the fourth electrode,
wherein when an alternating current voltage is applied to the third electrode and the fourth electrode and no standing acoustic wave is applied to the matrix unit through the first electrode and the second electrode, the conductive particles in the fluid migrate by dielectrophoresis to form a conductive bridge connecting the third electrode and the fourth electrode in an upper portion of the fluid, thereby inducing light emission from the electroluminescent layer,
wherein when a standing acoustic wave is applied through the first electrode and the second electrode while the conductive bridge is formed, the conductive particles migrate toward nodes of the standing acoustic wave and the conductive bridge is disrupted, resulting in extinction of light emission from the electroluminescent layer, and
wherein the temperature sensing device further comprises a controller configured to adjust the frequency of the acoustic wave power supply.

11. The temperature sensing device of claim 10, wherein the first electrode and the second electrode are formed facing each other with the substrate interposed therebetween, and the acoustic wave formed by the acoustic wave power supply is a bulk acoustic wave.

12. The temperature sensing device of claim 10, wherein the first electrode and the second electrode are formed coplanar and spaced apart from each other on the substrate, and the acoustic wave formed by the acoustic wave power supply is a surface acoustic wave.

13. The temperature sensing device of claim 10, wherein the temperature sensing device senses temperature by utilizing a shift in the frequency at which the acoustic wave power supply is configured to form a standing acoustic wave to disrupt the conductive bridge, the shift occurring when acoustic transmission properties of the fluid change due to a variation in temperature.

14. A foreign substance sensing device comprising a dual-sensing alternating current electroluminescent device, the dual-sensing alternating current electroluminescent device comprising:
an acoustic wave generating unit comprising: a substrate; a first electrode formed adjacent to the substrate; and a second electrode formed adjacent to the substrate and spaced apart from the first electrode;
a matrix unit positioned on the acoustic wave generating unit and comprising: a chamber capable of receiving a fluid therein; a fluid received within the chamber; and conductive particles dispersed in the fluid;
an electroluminescent layer positioned on the matrix unit and configured to emit light when a voltage is applied thereto;
a third electrode positioned on the electroluminescent layer and formed coplanar with the electroluminescent layer;
a fourth electrode positioned on the electroluminescent layer, formed coplanar with the electroluminescent layer, and spaced apart from the third electrode;
an acoustic wave power supply configured to apply a voltage to the first electrode and the second electrode to form a standing acoustic wave in the matrix unit; and
an alternating current power supply configured to apply an alternating current voltage to the third electrode and the fourth electrode,
wherein a fluid channel through which a second fluid passes is further formed between the substrate and the matrix unit,
wherein when an alternating current voltage is applied to the third electrode and the fourth electrode and no standing acoustic wave is applied to the matrix unit through the first electrode and the second electrode, the conductive particles in the fluid migrate by dielectrophoresis to form a conductive bridge connecting the third electrode and the fourth electrode in an upper portion of the fluid, thereby inducing light emission from the electroluminescent layer,
wherein when a standing acoustic wave is applied through the first electrode and the second electrode while the conductive bridge is formed, the conductive particles migrate toward nodes of the standing acoustic wave and the conductive bridge is disrupted, resulting in extinction of light emission from the electroluminescent layer, and
wherein the foreign substance sensing device is capable of sensing a foreign substance within the fluid channel.

15. The foreign substance sensing device of claim 14, wherein the first electrode and the second electrode are formed facing each other with the substrate interposed therebetween, and the acoustic wave formed by the acoustic wave power supply is a bulk acoustic wave.

16. The foreign substance sensing device of claim 14, wherein the first electrode and the second electrode are formed coplanar and spaced apart from each other on the substrate, and the acoustic wave formed by the acoustic wave power supply is a surface acoustic wave.

17. The foreign substance sensing device of claim 14, wherein the foreign substance sensing device senses a change in light emission intensity of the electroluminescent layer that occurs as a result of disruption and formation of the conductive bridge, the disruption and formation being caused by a change in whether the standing acoustic wave is formed, which in turn occurs when acoustic transmission properties of a material passing through the fluid channel change.

18. The foreign substance sensing device of claim 14, wherein the foreign substance is a substance other than the second fluid or an air bubble.
